(19) United States
(12) Patent Application Publication
(10) Pub. No.: US 2026/0033359 A1
(43) Pub. Date: Jan. 29, 2026

(54) CONNECTING ELEMENT FOR SEMICONDUCTOR DEVICES

(71) Applicant: ADEIA SEMICONDUCTOR BONDING TECHNOLOGIES INC., San Jose, CA (US)

(72) Inventors: Cyprian Emeka Uzoh, San Jose, CA (US); Rajesh Katkar, Milpitas, CA (US); Belgacem Haba, Saratoga, CA (US)

(21) Appl. No.: 18/785,793

(22) Filed: Jul. 26, 2024

(51) Int. Cl. H01L 23/538; H01L 23/00; H01L 23/473; H01L 23/48; H01L 25/18; H10B 80/00

(52) U.S. Cl. CPC H01L 23/5386; H01L 23/481; H01L 25/18; H10B 80/00; H01L 23/473; H01L 24/08; H01L 24/48; H01L 24/96; H01L 24/97; H01L 2224/08145; H01L 2224/08225; H01L 2224/48225; H01L 2224/96; H01L 2224/97; H01L 2924/1431; H01L 2924/1432; H01L 2924/1436; H01L 2924/182

(57) ABSTRACT

A structure is disclosed. The structure can include a first processor die, a second processor die, a first memory unit, and a connecting element. The second processor die can be laterally spaced from the first processor die. The first memory unit can be disposed vertically above the first processor die. The connecting element can be disposed vertically to the first processor die and the second processor die. The connecting element can include a conductor electrically connecting the first processor die and the second processor die.

### BACKGROUND

### Field

This disclosure relates to semiconductor device structures and methods. In particular, some embodiments are directed to methods and structures for bridging semiconductor dies.

### Description of Related Art

The approaches described in this section are approaches that could be pursued, but not necessarily approaches that have been previously conceived or pursued. Therefore, unless otherwise indicated, it should not be assumed that any of the approaches described in this section qualify as prior art merely by virtue of their inclusion in this section.

As sizes of processor chips continue to increase, multiple processor chiplets may be stitched with each other to form a monolithic processor chip. Increasing memory bandwidth of a processor chiplet, reducing memory latency of a processor chiplet, and/or conserving amount of connecting elements used for connecting processor chiplets and memories can be challenging for packaging the monolithic processor chip.

### BRIEF DESCRIPTION OF THE DRAWINGS

These and other features, aspects, and advantages of the disclosure are described with reference to drawings of certain embodiments, which are intended to illustrate, but not to limit, the present disclosure. It is to be understood that the accompanying drawings, which are incorporated in and constitute a part of this specification, are for the purpose of illustrating concepts disclosed herein and may not be to scale.

FIG. 1A illustrates a top schematic view and a side schematic sectional view of a bonded structure with high bandwidth memories stacked around a periphery of processor dies.

FIG. 1B illustrates a side schematic sectional view of a bonded structure with high bandwidth memories stacked above processor dies according to some embodiments.

FIG. 1C illustrates a top schematic view of the bonded structure of FIG. 1B according to some embodiments.

FIG. 2 illustrates a side schematic sectional view of an example implementation of a bonded structure with high bandwidth memories stacked above processor dies according to some embodiments.

FIG. 3 illustrates a side schematic sectional view of another example implementation of a bonded structure with high bandwidth memories stacked above processor dies according to some embodiments.

FIG. 4 illustrates a side schematic sectional view of another example implementation of a bonded structure with high bandwidth memories stacked above processor dies according to some embodiments.

FIG. 5 illustrates a side schematic sectional view of another example implementation of a bonded structure with high bandwidth memories stacked above processor dies according to some embodiments.

FIG. 6 illustrates a side schematic sectional view of another example implementation of a bonded structure with high bandwidth memories stacked above processor dies according to some embodiments.

FIG. 7 illustrates side schematic sectional views of other example implementations of bonded structures with high bandwidth memories stacked above processor dies according to some embodiments.

FIG. 8 illustrates a top schematic view and a side schematic sectional view of a bonded structure with high bandwidth memories stacked above processor dies according to some embodiments.

FIG. 9 illustrates a top schematic view and a side schematic sectional view of another bonded structure with high bandwidth memories stacked above processor dies according to some embodiments.

FIG. 10 illustrates a side schematic sectional view of a bonded structure with high bandwidth memories stacked above processor dies according to some embodiments.

FIGS. 11A-11J illustrate an example process for assembling a bonded structure, such as the bonded structure of FIG. 1B, according to some embodiments.

FIGS. 12A-12F illustrate another example process for assembling a bonded structure, such as the bonded structure of FIG. 1B, according to some embodiments.

FIGS. 13A and 13B schematically illustrate cross-sectional side views of two elements prior to and after, respectively, a process for forming a directly bonded structure, and more particularly a hybrid bonded structure, according to some embodiments.

### SUMMARY

The systems, methods, and devices described herein each have several aspects, no single one of which is solely responsible for its desirable attributes. Without limiting the scope of this disclosure, several non-limiting features will now be described briefly.

In some aspects, the techniques described herein relate to a structure including: a first processor die; a second processor die laterally spaced from the first processor die; a first memory unit disposed vertically above the first processor die; and a connecting element disposed vertically between the first memory unit and the first processor die, and vertically between the first memory unit and the second processor die, the connecting element including: a first conductor electrically connecting the first processor die and the second processor die; and a second conductor electrically connecting the first processor die and the first memory unit.

In some aspects, the techniques described herein relate to a structure, wherein the first memory unit includes a first stack of memory dies and a first input/output (I/O) interface logic.

In some aspects, the techniques described herein relate to a structure, wherein the first I/O interface logic is stacked below the first stack of memory dies.

In some aspects, the techniques described herein relate to a structure, wherein the first processor die communicates with the first memory unit at least through the second conductor.

In some aspects, the techniques described herein relate to a structure, wherein the second processor die communicates with the first memory unit at least through the second conductor and the first conductor.

In some aspects, the techniques described herein relate to a structure, further including a second memory unit disposed vertically above the second processor die, the second memory unit laterally spaced from the first memory unit, the connecting element disposed vertically between the first memory unit and the first processor die and vertically between the first memory unit and the second processor die.

In some aspects, the techniques described herein relate to a structure, wherein the second memory unit includes a second stack of memory dies.

In some aspects, the techniques described herein relate to a structure, wherein the connecting element includes a third conductor electrically connecting the second processor die and the second memory unit.

In some aspects, the techniques described herein relate to a structure, wherein the first processor die communicates with the second memory unit at least through the third conductor and the first conductor.

In some aspects, the techniques described herein relate to a structure, wherein the connecting element includes at least one of a dummy region, a passive component, an active component, an interface logic, a test pad.

In some aspects, the techniques described herein relate to a structure, wherein the connecting element includes a redistribution layer (RDL), the first conductor being in the RDL.

In some aspects, the techniques described herein relate to a structure, wherein the first processor die includes a first through substrate via (TSV), and wherein the second conductor is connected to the first TSV.

In some aspects, the techniques described herein relate to a structure, wherein the connecting element is hybrid bonded to the first processor die, the second processor die, and the first memory unit.

In some aspects, the techniques described herein relate to a structure, wherein the first processor die includes a first graphics processing unit (GPU) chiplet, wherein the second processor die includes a second GPU chiplet, and wherein the first GPU chiplet and the second GPU chiplet form a monolithic GPU.

In some aspects, the techniques described herein relate to a structure, wherein the connecting element is disposed vertically above a center of the monolithic GPU.

In some aspects, the techniques described herein relate to a structure, wherein the first memory unit is disposed vertically above the center of the monolithic GPU.

In some aspects, the techniques described herein relate to a structure, further including a third memory unit, the third memory unit disposed vertically above a left side or a right side of the monolithic GPU.

In some aspects, the techniques described herein relate to a structure, wherein the first processor die or the second processor die includes at least one of a system on a chip (SOC), a central processing unit (CPU), and a graphics processing unit (GPU).

In some aspects, the techniques described herein relate to a structure, wherein the first processor die or the second processor die is reconstituted.

In some aspects, the techniques described herein relate to a structure, wherein the connecting element is reconstituted.

In some aspects, the techniques described herein relate to a structure, further including a first cooling element disposed vertically directly above the first processor die and a second cooling element disposed vertically directly above the second processor die.

In some aspects, the techniques described herein relate to a structure, further including a substrate, the first processor die and the second processor die disposed on the substrate.

In some aspects, the techniques described herein relate to a structure, further including a semiconductor die disposed on the connecting element and laterally spaced from the first memory unit, wherein the semiconductor die is wire bonded to the substrate.

In some aspects, the techniques described herein relate to a structure including: a first processor die; a second processor die laterally spaced from the first processor die; a first memory unit disposed vertically above the first processor die; and a connecting element disposed vertically to the first processor die and the second processor die, the connecting element including: a first conductor electrically connecting the first processor die and the second processor die.

In some aspects, the techniques described herein relate to a structure, wherein the first processor die includes a first via, the second processor die communicating with the first memory unit at least through the first via and the first conductor.

In some aspects, the techniques described herein relate to a structure, wherein the first processor die communicates with the first memory unit at least through the first via.

In some aspects, the techniques described herein relate to a structure, wherein the connecting element is disposed vertically below the first processor die and the second processor die.

In some aspects, the techniques described herein relate to a structure, wherein the connecting element is disposed vertically above the first processor die and the second processor die, the connecting element disposed laterally relative to the first memory unit.

In some aspects, the techniques described herein relate to a structure, wherein the connecting element is disposed vertically between the first memory unit and the first processor die, and vertically between the first memory unit and the second processor die.

In some aspects, the techniques described herein relate to a structure, wherein the connecting element includes a second conductor electrically connecting the first processor die and the first memory unit.

In some aspects, the techniques described herein relate to a structure, wherein the first processor die communicates with the first memory unit at least through the second conductor.

In some aspects, the techniques described herein relate to a structure, wherein the second processor die communicates with the first memory unit at least through the second conductor and the first conductor.

In some aspects, the techniques described herein relate to a structure, further including a second memory unit disposed vertically above the second processor die, the second memory unit laterally spaced from the first memory unit, the connecting element disposed vertically between the first memory unit and the first processor die and vertically between the first memory unit and the second processor die.

In some aspects, the techniques described herein relate to a structure, wherein the second memory unit includes a second stack of memory dies.

In some aspects, the techniques described herein relate to a structure, wherein the connecting element includes a third conductor electrically connecting the second processor die and the second memory unit.

In some aspects, the techniques described herein relate to a structure, wherein the first processor die communicates with the second memory unit at least through the third conductor and the first conductor.

In some aspects, the techniques described herein relate to a structure, wherein the connecting element includes at least one of a dummy region, a passive component, an active component, an interface logic, a test pad.

In some aspects, the techniques described herein relate to a structure, wherein the connecting element includes a redistribution layer (RDL), the first conductor being in the RDL.

In some aspects, the techniques described herein relate to a structure, wherein the first processor die includes a first through substrate via (TSV), and wherein the second conductor is connected to the first TSV.

In some aspects, the techniques described herein relate to a structure, wherein the connecting element is hybrid bonded to the first processor die, the second processor die, and the first memory unit.

In some aspects, the techniques described herein relate to a structure, wherein the first processor die includes a first graphics processing unit (GPU) chiplet, wherein the second processor die includes a second GPU chiplet, and wherein the first GPU chiplet and the second GPU chiplet form a monolithic GPU.

In some aspects, the techniques described herein relate to a structure, wherein the connecting element is disposed vertically above a center of the monolithic GPU.

In some aspects, the techniques described herein relate to a structure, wherein the first memory unit is disposed vertically above the center of the monolithic GPU.

In some aspects, the techniques described herein relate to a structure, further including a third memory unit, the third memory unit disposed vertically above a left side or a right side of the monolithic GPU.

In some aspects, the techniques described herein relate to a structure, wherein the first processor die or the second processor die includes at least one of a system on a chip (SOC), a central processing unit (CPU), and a graphics processing unit (GPU).

In some aspects, the techniques described herein relate to a structure, wherein the first processor die or the second processor die is reconstituted.

In some aspects, the techniques described herein relate to a structure, wherein the connecting element is reconstituted.

In some aspects, the techniques described herein relate to a structure, further including a first cooling element disposed vertically directly above the first processor die and a second cooling element disposed vertically directly above the second processor die.

In some aspects, the techniques described herein relate to a structure, further including a substrate, the first processor die and the second processor die disposed on the substrate.

In some aspects, the techniques described herein relate to a structure, further including a semiconductor die disposed on the connecting element and laterally spaced from the first memory unit, wherein the semiconductor die is wire bonded to the substrate.

In some aspects, the techniques described herein relate to a method for forming a bonded structure, the method including: bonding a first side of a first processor die to a first side of a substrate; bonding a first side of a second processor die to the first side of the substrate; bonding a first side of a connecting element to a second side of the first processor die and a second side of the second processor die, the second side of the first processor die being opposite to the first side of the first processor die, and the second side of the second processor die being opposite to the first side of the second processor die; and bonding a first memory unit to a second side of the connecting element, the second side of the connecting element being opposite to the first side of the connecting element, wherein the connecting element is configured to electrically connect the first processor die, the second processor die, and the first memory unit.

In some aspects, the techniques described herein relate to a method, wherein the connecting element provides lateral communication between the first processor die and the second processor die, and vertical communication between the first memory unit and the first processor die.

In some aspects, the techniques described herein relate to a method, wherein bonding the first side of the connecting element uses direct bonding.

In some aspects, the techniques described herein relate to a method, wherein bonding the first memory unit to the second side of the connecting element uses direct bonding.

In some aspects, the techniques described herein relate to a method, further including direct bonding a second memory unit to the second side of the connecting element.

In some aspects, the techniques described herein relate to a method, further including routing a first plurality of connectors through the connecting element to electrically connect the first processor die and the second processor die.

In some aspects, the techniques described herein relate to a method, further including routing a second plurality of connectors through the connecting element to electrically connect the first processor die and the first memory unit.

In some aspects, the techniques described herein relate to a method, further including coating a dielectric layer on the second side of the first processor die and the second side of the second processor die prior to bonding the first side of the connecting element.

In some aspects, the techniques described herein relate to a method, further including planarizing the dielectric layer to expose one or more contact pads on the second side of the first processor die or the second side of the second processor die prior to bonding the first side of the connecting element.

In some aspects, the techniques described herein relate to a method, further including activating the second side of the first processor die and the second side of the second processor die prior to bonding the first side of the connecting element.

In some aspects, the techniques described herein relate to a method, further including annealing the first side of the connecting element, the second side of the first processor die, and the second side of the second processor die.

In some aspects, the techniques described herein relate to a method, further including activating the second side of the connecting element prior to bonding the first memory unit to the second side of the connecting element.

In some aspects, the techniques described herein relate to a method, further including adding one or more test pads on the second side of the connecting element prior to bonding the first memory unit to the second side of the connecting element.

In some aspects, the techniques described herein relate to a method, further including annealing the first memory unit and the second side of the connecting element.

In some aspects, the techniques described herein relate to a method, further including mounting the bonded structure on a frame for singulation.

In some aspects, the techniques described herein relate to a method, further including coating a protective layer over the bonded structure mounted on the frame, and singulating the bonded structure mounted on the frame.

In some aspects, the techniques described herein relate to a method, further including stripping the protective layer from the bonded structure that is singulated.

In some aspects, the techniques described herein relate to a method, further including cleaning and drying the bonded structure that is singulated.

In some aspects, the techniques described herein relate to a method, wherein the first processor die or the second processor die includes at least one of a system on a chip (SOC), a central processing unit (CPU), and a graphics processing unit (GPU).

In some aspects, the techniques described herein relate to a method, wherein the first memory unit includes a first stack of memory dies.

In some aspects, the techniques described herein relate to a method, wherein bonding the first side of the connecting element uses direct bonding.

In some aspects, the techniques described herein relate to a method, wherein bonding the first memory unit to the second side of the connecting element uses direct bonding.

Various combinations of the above and below recited features, embodiments, and aspects are also disclosed and contemplated by the present disclosure.

Additional embodiments of the disclosure are described below in reference to the appended claims, which may serve as an additional summary of the disclosure.

### DETAILED DESCRIPTION

Although several embodiments, examples, and illustrations are disclosed below, it will be understood by those of ordinary skill in the art that the disclosure described herein extends beyond the specifically disclosed embodiments, examples, and illustrations and includes other uses of the disclosure and obvious modifications and equivalents thereof. Embodiments are described with reference to the accompanying figures, wherein like numerals refer to like elements throughout. The terminology used in the description presented herein is not intended to be interpreted in any limited or restrictive manner simply because it is being used in conjunction with a detailed description of some specific embodiments of the disclosure. In addition, embodiments can comprise several novel features. No single feature is solely responsible for its desirable attributes or is essential to practicing the disclosure herein described.

Bridges and interposers are useful for connecting processor and memory dies in a semiconductor package. However, it can be challenging to cost effectively implement low latency and high bandwidth connections between processor and memory dies, particularly when areas of processors increase. Some embodiments disclosed herein nevertheless accomplish low latency and high bandwidth memory access for processor dies using reduced number of connecting elements that perform dual functionalities of stitching processor dies with each other and providing interconnections between processor dies and memory dies, and between different processor dies in the package.

There is increasing demand for higher memory bandwidth and higher memory capacity. Providing high speed, high bandwidth connections between memory and processors can be important for some applications. For example, when training an artificial intelligence or machine learning model, performing complex graphical operations, or carrying out other data-intensive tasks, processors such as central processing units (CPUs), graphical processing units (GPUs), field programmable gate arrays (FPGAs), application specific integrated circuits (ASICs), and so forth can spend a significant amount of time idle while waiting for data, which can negatively impact performance and increase the time it takes to complete computing tasks.

In conventional semiconductor packages, high bandwidth memories (HBMs) implemented using stacked memory units may be positioned adjacent and connected to a processor (e.g., a GPU or a CPU) through a bridge. For example, memory dies (e.g., DRAM dies) can be positioned laterally to a periphery of a GPU and connected to the GPU through a bridge that includes high density connecting traces and/or vias. However, a typical lateral conductive trace connecting the GPU and the memory dies may be about 3 millimeter (mm) to 6 mm in length. For example, I/O interfaces associated with GPUs and/or HBMs may be designed to be at the neighboring edges of the respective chips, and a maximum separation between the farthest ends of the I/O interfaces can be around 5 mm to 6 mm in length. Such length of connecting conductor may constrain time required for data transfer and pose a bottleneck to memory latency. The lateral (side by side) placement of processor dies and HBMs also occupy additional premium real estate on the substrate they are mounted on (e.g. interposer, embedded substrate, etc.)

Additionally, achieving efficient memory access may become more challenging as demands on computing power continue to increase. More specifically, as sizes of processor chips continue to increase toward or beyond reticle sizes, multiple processor chiplets may be stitched or connected together using massive interposers or bridges to form a large monolithic processor chip. For an individual processor chiplet, latency associated with memories located adjacent or closer to the processor chiplet can be high because of increased chip size of the individual processor chiplet. Further, latency associated with memories located farther away (e.g., memories that are separated from a processor chiplet by another processor chiplet or another memory stack) from the processor chiplet can be higher at least due to the presence of the other processor chiplets (or memory stack) and the presence of additional bridges used for connecting processor chiplets and HBMs. This may prevent the processor chiplets from effectively accessing certain HBMs, thereby compromising data transfer efficiency (e.g., reducing memory bandwidth). Also, the additional bridges for connecting adjacent processor chiplets may increase cost and area for packaging besides adding memory latency as noted above.

Alternatively, processor chiplets and memory stacks can also be mounted on very large interposer(s). But such interposers can be very expensive, and can face reliability issues (e.g. excessive warpage) and low manufacturing yield. Although bridges that are more economical can be used to replace such massive interposers, manufacturing process to integrate several bridges within an underlying substrate (e.g. PCB or fanout wafer/panel) can also be very cumbersome and expensive.

To address at least a portion of the aforementioned problems, some embodiments herein utilize one or more connecting elements (e.g., a bridge interposer, a bridge) to stitch processor chiplets (e.g., GPU, CPU, TPU, NPU, or the like) together while enabling communications between the processor chiplets and memory units that are stacked vertically above the processor chiplets. In some examples, a bridge interposer is disposed between a plurality of processor chiplets and one or more memory units that are stacked on or above the bridge interposer and the plurality of processor chiplets. Advantageously, memory latency may be significantly reduced. More specifically, instead of connecting a processor chiplet and a memory unit (e.g., a plurality of DRAM dies and optional logics) using lateral conductive traces that may be about 3 mm to 6 mm in length as noted above, the processor chiplet and the memory unit may be connected using vertical passthrough (e.g., vias) that may be significantly shorter (e.g., between 200 μm to 300 μm), and at the same time, shrink the footprint of the multi chip assembly to only the foot print of the processor chiplets.

Additionally and/or optionally, one or more memory units may be stacked near a center of a monolithic processor chip, which helps to achieve low latency memory access to cores or interior portions of the monolithic processor chip. Advantageously, memory bandwidth for a processor chiplet may be increased at least because the processor chiplet can efficiently access the one or more memory units stacked near the center as well as memory units around the periphery of processor chiplets. Further, through a connecting element, a memory unit can be shared by a plurality of processor chiplets. In some examples, many-to-many communications can be accomplished among a plurality of processor chiplets and a plurality of memory units through a single connecting element. Advantageously, the one or more connecting elements can achieve low latency and high bandwidth communication between memory units and processor chiplets without causing much area overhead of a semiconductor package.

As used herein, the term “processor chiplet” (can also be referred to as “processor die”) can refer to least a central processing unit (CPU) die, a graphic processing unit (GPU) die, a neural networking processing unit (NPU) die, or a tensor processing unit (TPU) die. Multiple processor chiplets may be stitched or connected together to form a monolithic processor chip, such as a multicore GPU, a multicore CPU, a multicore NPU, a multicore TPU, or the like.

### Example Bonded Structure

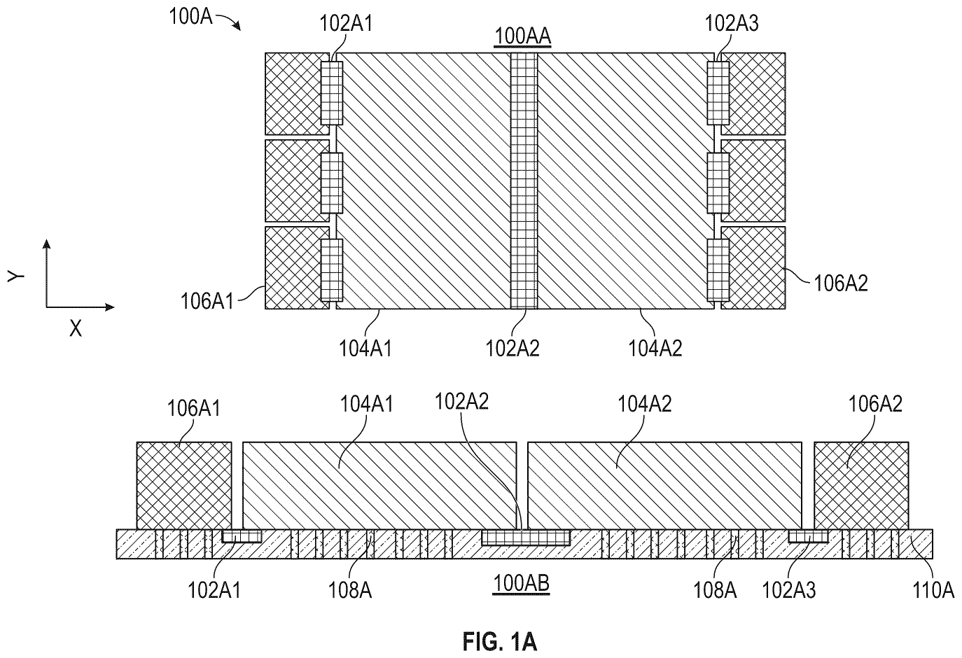

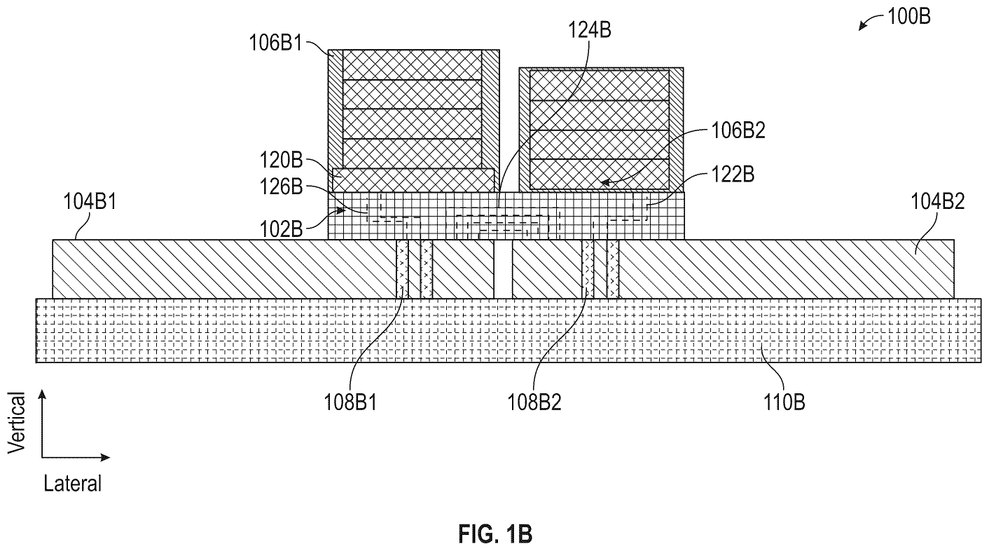

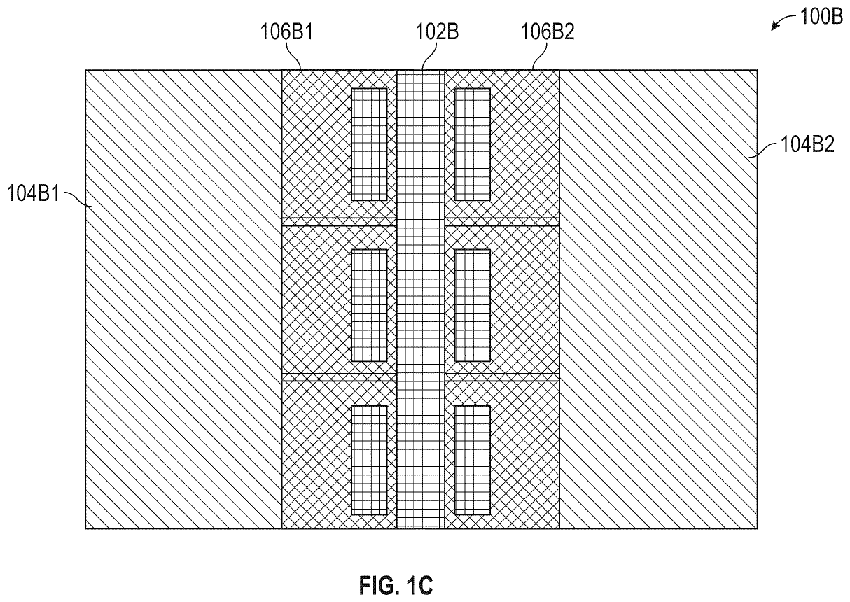

FIG. 1A illustrates a top schematic view 100AA and a side schematic sectional view 100AB of a package structure 100A that includes a bridge 102A1, a bridge 102A2, a bridge 102A3, a GPU die 104A1, a GPU die 104A2, a memory unit 106A1, a memory unit 106A2, vias 108A, and a substrate 110A. As shown in FIG. 1A, the memory units 106A1, 106A2 are positioned around the periphery of GPU dies 104A1, 104A2. The memory units 106A1, 106A2 and the GPU dies 104A1, 104A2 are shown to be mounted on the substrate 110A. The memory units 106A1, 106A2 and the GPU dies 104A1, 104A2 are electrically connected with each other through the bridges 102A1, 102A2, and 102A3. For example, the memory unit 106A1 can be electrically connected to the GPU die 104A1 through the bridge 102A1; the GPU die 104A1 can be electrically connected to the GPU die 104A2 through the bridge 102A2; and the GPU die 104A2 can be electrically connected to the memory unit 106A2 through the bridge 102A3. Each of the bridges 102A1, 102A2, and 102A3 can comprise routing layers (not shown) embedded in a dielectric as a part of the substrate 110A. In some examples, the substrate 110A can be an organic substrate, a printed circuit board (PCB), a mold compound (e.g. fanout wafer/panel level reconstitution of bridge chips), or other types of substrate in which the bridges 102A1, 102A2, and 102A3 are at least partially embedded. The memory unit 106A1 may be laterally spaced from the GPU die 104A1, and may be connected to the GPU die 104A1 through transmission lines that include lateral conductive traces in routing layers of the bridge 102A1. The memory unit 106A2 may be laterally spaced from the GPU die 104A2, and may be connected to the GPU die 104A2 through transmission lines that include lateral conductive traces in routing layers of the bridge 102A3. A GPU die 104A1, a GPU die 104A2, a memory unit 106A1, and/or a memory unit 106A2 can also be mounted directly on a large silicon (or glass) interposer without the need of bridge chips; with high density connection routing between the memory units and GPU dies formed in the interposer. However, such large interposers (e.g. >60×60 mm in footprint) are cost prohibitive (due to significantly large area of silicon and/or bridges), add manufacturing complexities with low yield and introduce reliability challenges during assembly and operation (e.g. warpage).

A via 108A extends vertically through the substrate 110A. The via 108A may provide electrical connections for the memory units 106A1, 106A2 and the GPU dies 104A1, 104A2. The substrate 110A may provide structural support to the memory units 106A1, 106A2 and the GPU dies 104A1, 104A2. The substrate 110A may provide mechanical stability to the bonded structure 100A and accommodate the bridges 102A1, 102A2, and 102A3 to facilitate communication between the memory units and the GPU dies. An additional redistribution layer (RDL) can also be deposited on top of the substrate 110A to provide additional routing flexibility. RDL can also be formed at the bottom of the substrate 110A. The implementations shown in FIG. 1A can suffer several drawbacks. First, latency for data transfer between the GPU die 104A1 and the memory unit 106A1 may be high due to the long transmission lines in the bridge 102A1. Second, it may be unfeasible for the GPU die 104A2 to access the memory unit 106A1 because latency for data transfer between the GPU die 104A2 and the memory unit 106A1 may need to go through at least the bridge 102A1, the GPU die 104A1, and the bridge 102A2, which may be too high for certain applications. Third, the bonded structure 100A uses bridges 102A1, 102A3 to facilitate communications between the GPU dies 104A1, 104A2 and the memory units 106A1, 106A2, in addition to using the bridge 102A2 for electrically connecting GPU dies 104A1, 104A2. The increased number of bridges may lead to increased cost and complexity in packaging the bonded structure 100A.

As illustrated in the example implementation of FIG. 1A, the long direction of the bridge 102A2 and the long direction of the bridges 102A1 and 102A3 are in parallel (e.g., both along the Y direction). In another example, the long direction of the bridge 102A2 and the long direction of the bridges 102A1 and 102A3 can be orthogonal (e.g., the long direction of the bridges 102A1 and 102A3 can be along the X direction, and the long direction of the bridge 102A2 can be along the Y direction). It should be noted that a reticle (e.g., a maximum size of the GPU die 104A1 or the GPU die 104A2) can be 26 mm×32 mm in area, and a combined size of the GPU die 104A1 and the GPU die 104A2 can be 52 mm×32 mm. In both examples, the distance between farthest HBMs can be longer than a length of the GPU die 104A1 (or the GPU die 104A2) in either the X direction or the Y direction.

As noted above, some implementations disclosed herein can significantly improve latency and increase memory bandwidth by using one or more connecting elements to stitch processor chiplets while enable communication between the processor chiplets and memory units that are stacked vertically above the processor chiplets. For example, a connecting element may be disposed between the processor chiplets and the memory units that are stacked above the connecting element and the processor chiplets. The connecting element may facilitate communication between the processor chiplets and the memory units under low latency and with high memory bandwidth.

Example Bonded Structures 100B with high bandwidth memories stacked above processor dies according to some embodiments. The bonded structure 100B includes a connecting element 102B, processor dies 104B1, 104B2, memory units 106B1, 106B2, vias 108B1, 108B2, a substrate 110B, logic 120B, conductors 122B, 124B, 126B. FIG. 1C illustrates a top schematic view of the bonded structure 100B.

As shown in FIG. 1B, the substrate 110B can be a nonconductive or insulating base substrate with conductive routing traces (not shown) (e.g., at least partially embedded traces), such as a laminate substrate, a printed circuit board (PCB) substrate, a semiconductor interposer (e.g. silicon interposer), a glass interposer, a reconstituted structure with one or more die(s) at least partially embedded in an organic or inorganic encapsulant, a flexible substrate comprising a polymer with embedded traces, an integrated device die or wafer, or any other suitable substrate. The conductive routing traces can laterally and/or vertically transfer signals through the substrate 110B in various implementations, such as to connect to terminals on various sides of the substrate 110B, which in turn can be connected to a system board or other components within the larger electronic system.

The processor dies 104B1, 104B2 are shown to be disposed (e.g., bonded) on the substrate 110B. In some examples, the processor die 104B1 and/or the processor die 104B2 can be soldered to the substrate 110B or hybrid bonded to the substrate 110B if the substrate 110B has a bondable surface. The processor dies 104B1, 104B2 can be GPU dies, CPU dies, TPU dies, NPU dies, and/or any combination thereof. In some examples, each of the processor dies 104B1, 104B2 can be a GPU chiplet. The processor die 104B1 can include via 108B1 that facilitate data transfer within the processor die 104B1 and/or with other components of the bonded structure 100B. The processor die 104B2 can include via 108B2 that facilitate data transfer within the processor die 104B2 and/or with other components of the bonded structure 100B. For example, the via 108B1 may establish electrical connections among various layers of the processor die 104B1, and/or establish electrical connections with the connecting element 102B to facilitate communication between the processor die 104B1 and the memory units 106B1, 106B2. In some examples, the vias 108B1, 108B2 may be implemented as through-substrate-vias (TSVs) to provide passthrough that goes through the processor dies 104B1, 104B2. In these examples, the via 108B1 may provide communication between the connecting element 102B and the substrate 110B besides connecting various parts of the processor die 104B1. The via 108B2 may provide communication between the connecting element 102B and the substrate 110B besides connecting various parts of the processor die 104B2.

The connecting element 102B can be disposed (e.g., bonded, such as directly bonded or deposited such as build up wiring layers) above the processor dies 104B1, 104B2. For example, the connecting element 102B can be hybrid bonded to each of the processor dies 104B1, 104B2. The connecting element 102B can provide at least electrical communication between one or more of the processor dies 104B1, 104B2, and one or more of the memory units 106B1, 106B2. For example, the connecting element 102B can connect the processor die 104B1 to either the memory unit 106B1 or the memory unit 106B2. As another example, the connecting element 102B can connect the processor die 104B2 to either the memory unit 106B1 or the memory unit 106B2. As still another example, the connecting element 102B can connect the processor die 104B1 to the processor die 104B2. As yet another example, the connecting element 102B can connect the first memory unit 106B1 to the second memory unit 106B2. The connecting element 102B can comprise one or more layers and materials for facilitating electrical communication. For example, the connecting element 102B can include one or more conductive layers that accommodate the conductors 122B, 124B, 126B. The conductors 122B, 124B, 126B may each include one or more vias (e.g., vertical electrical connections) and/or one or more traces (e.g., lateral electrical connections). In some implementations, a thickness or height (e.g., a length in a vertical direction) of the connecting element 102B can be around 5 micrometer (μm) to 300 μm. As such, a length of the conductors 122B, 124B, 126B (e.g., a vertical passthrough trace), may be as short as about 0.3 μm to 300 μm. In other implementations, the length of the conductors 122B 124B, 126B can be shorter than 0.3 μm or longer than 300 μm. For example, the length of the conductors 122B, 124B and 126B can be about 2 mm in situations where standard I/O blocks (e.g., the logic 120B) associated with the memory units 106B1 and 106B2 or the processor dies 104B1 and 104B2 are around 1 mm to 1.5 mm in the lateral direction.

The connecting element 102B can further include one or more dielectric layers (not shown) that surround the one or more conductive layers to provide electrical insulation and structural support. In some examples, the one or more dielectric layers can include inorganic layers, such as silicon oxide, silicon nitride, silicon oxynitride, silicon carbonitride, or any other dielectric that can form a hybrid bondable surface. Additionally or alternatively, the one or more dielectric layers can include one or more organic layers with bondable dielectric(s), such as inorganic dielectric, disposed over or under the organic layers. The connecting element 102B can additionally and/or optionally include one or more redistribution layers (RDL). The one or more RDL may be deployed on one or both sides (e.g., a first side of the connecting element 102B that is bonded to the processor dies 104B1, 104B2, and a second side of the connecting element 102B to which the memory units 106B1, 106B2 are bonded) of the connecting element 102B to allow the processor dies 104B1, 104B2 to access the memory units 106B1, 106B2. In some embodiments, the connecting element 102B may comprise passive elements such as resistors, capacitors, inductors, micro-electrical mechanical system (MEMS), optical elements, and/or the like. In some embodiments, the connecting element 102B may comprise an active (or functional) silicon (e.g. active bridge or active interposer). In some embodiments, the length of the connecting element 102B along the lateral direction (e.g., a width of the connecting element 102B) is at least longer than the length of the memory units 106B1 and/or 106B2 along the lateral direction (e.g., a width of the memory unit 106B1).

The memory unit 106B1 can be disposed (e.g., bonded, such as directly bonded using ZIBOND® or DBI® hybrid bonding technique without adhesive or an intervening layer or flip chipped or micro-bumped) on the connecting element 102B to be vertically above the processor die 104B1. The memory unit 106B1 can comprise a plurality of (e.g., two, three, four, five, twelve, sixteen, or the like) memory dies (e.g., DRAM dies) hybrid bonded to and stacked on one another. Here, FIG. 1B illustrates a non-limiting example of the memory unit 106B1 having four memory dies. The memory dies of the memory unit 106B1 may communicate with the base die or logic 120B of the memory unit 106B1. The logic 120B can be a logic die or controller die, and can include various logic (e.g., input/output (I/O) interface logic) to facilitate communications between memory dies of the memory unit 106B1 and the processor dies 104B1, 104B2. For example, the logic 120B can manage data communicated to or from the stack of memory dies (e.g., data sent to and/or received from the processor dies 104B1, 104B2, or other devices) of the memory unit 106B1. Although not shown, TSVs can extend through the memory dies of the memory unit 106B1 to provide communication with the logic 120B. Further, the logic die and/or memory unit 106B1 can be encapsulated by one or more encapsulants, such as inorganic dielectric (e.g., silicon oxide, silicon nitride, etc.) or an organic dielectric (e.g., a polymeric material like resin, epoxy molding compound, etc.).

The memory unit 106B2 can be disposed (e.g., bonded, such as directly bonded using ZIBOND® or DBI® hybrid bonding technique without adhesive or an intervening layer) on the connecting element 102B to be vertically above the processor die 104B2. The memory unit 106B2 may include components the same as or similar to those described above with regard to the memory unit 106B1. Here, FIG. 1B illustrates a non-limiting example of the memory unit 106B2 having four memory dies but without a logic controller die, in contrast to the memory unit 106B1. In some examples, although not illustrated in FIG. 1B, a logic controller die (e.g., the logic 120B) can be integrated as a part of the connecting element 102B to facilitate communications between memory dies of the memory unit 106B2 and the processor dies 104B1, 104B2. As such, in some examples, the connecting element 102B can be a dummy interconnect element. In other examples, the connecting element 102B can further comprise a semiconductor element with active circuitry (e.g., a logic controller for one or more memory units, cache (e.g. L1, L2, L3 cache), network on chip (NOC), switch chip (e.g. network switch), accelerator fabric links, IO interfaces, PCIe express, HBM interface, fuse, photonic IC, laser, photodiode, etc.) and passive circuitry (e.g., capacitors, resistors, inductors, or the like). Although FIG. 1B illustrates two memory units 106B1, 106B2 disposed above the connecting element 102B, it should be noted that in some implementations there may be more or fewer memory units disposed above the connecting element 102B. For example, the bonded structure 100B may include the memory unit 106B1 without including the memory unit 106B2, or vice versa. In some examples, each of the memory units 106B1 and 106B2 can include four, eight, twelve, sixteen, or other number of memory dies. For example, each of the memory units 106B1 and 106B2 may include eight memory dies such that the memory units 106B1 and 106B2 include sixteen memory dies. Advantageously, the number of memory dies accessible to the processor die 104B1 and/or the processor die 104B2 via a controller die (e.g., the logic 120B) can be increased (e.g., doubled). In some examples, the number of memory dies in a memory stack or a memory unit (e.g., the memory unit 106B1 or 106B2) can be limited to be below certain number, thereby increasing yield associated with the bonded structure 100B.

In some examples, the processor dies 104B1, 104B2 are laterally spaced from each other. The memory unit 106B1 is disposed vertically above the processor die 104B1. The memory unit 106B2 is disposed vertically above the processor die 104B2. The connecting element 102B is disposed vertically between the memory unit 106B1 and the processor die 104B1, and vertically between the memory unit 106B1 and the processor die 104B2. The connecting element 102B includes the conductors 122B, 124B, 126B. The conductor 124B electrically connects the processor dies 104B1, 104B2. The conductor 126B electrically connects the processor die 104B1 and the memory unit 106B1. The memory unit 106B1 may include a stack of memory dies (e.g., four memory dies) and the logic 120B stacked below the stack of memory dies. The processor die 104B1 may communicate with the memory unit 106B1 at least through the conductor 126B. The processor die 104B2 may communicate with the memory unit 106B1 at least through the conductors 126B, 124B. It should be noted that the processor die 104B1, the processor die 104B2, the memory unit 106B1, and/or the memory unit 106B2 can be bonded face down. The connecting element 102B, if including active circuitry, can be bonded face down or face up.

In some examples, the memory unit 106B2 may be disposed vertically above the processor die 104B2. The memory unit 106B2 may be laterally spaced from the memory unit 106B1. The connecting element 102B may be disposed vertically between the memory unit 106B2 and the processor die 104B1, and vertically between the memory unit 106B2 and the processor die 104B2. The connecting element 102B may include the conductor 122B that electrically connects the processor die 104B2 and the memory unit 106B2. The processor die 104B1 may communicate with the memory unit 106B2 at least through the conductors 122B, 124B.

In contrast to the implementations of FIG. 1A, the bonded structure 100B offers several advantages. First, latency for data transfer between the processor dies 104B1, t104B2, and the memory units 106B1, 106B2 may be significantly reduced. For example, instead of connecting the processor die 104B1 and the memory unit 106B1 using lateral conductive traces that may be about 3 mm to 6 mm in length, the processor die 104B1 and the memory unit 106B1 may vertically communicate with each other through the conductor 126B (e.g., vertical passthrough traces) that may be between 5 μm to 300 μm. Additionally, by disposing the memory units 106B1, 106B2 above and near a center of a monolithic processor formed by the processor dies 104B1, 104B2, low latency memory access for cores or interior portions of the monolithic processor can be accomplished. Further, instead of using multiple bridges to facilitate communications between the processor dies and memory units, the bonded structure 100B can achieve many-to-many communication between the processor dies 104B1, 104B2 and the memory units 106B1, 106B2 through the connecting element 102B, thereby reducing costs and packaging sizes associated with packaging the bonded structure 100B. For example, multiple processor dies (e.g. 104B1, 104B2) can access multiple memory stacks (e.g. 106B1, 106B2) with a connector element providing comparable low latency connections between all the chiplets/stacks.

In some examples, although not shown in FIG. 1B, the connecting element 102B may include at least one of a dummy region, a passive component, an active component, an interface logic, and/or a test pad. In these examples, the connecting element 102B may be embodied as a bridge interposer, a bridge chip, or the like. The dummy region may be an area within the connecting element 102B that does not contain active circuitry or functional components. The dummy region can be used to provide structural support, manage thermal expansion, maintain mechanical stability, balance layout, or ensure uniformity in the manufacturing process of the bonded structure 100B. The passive component may be an electrical component (e.g., a resistor, a capacitor, an inductor, or the like) that does not require an external power source to operate. The passive component can be used for signal conditioning, filtering, impedance matching, and other functions that do not involve active amplification or switching. The active component can include a transistor, a diode, an integrated circuit that can be used for signal processing, amplification, and other functions that require active control of the electrical signals. The interface logic may serve as a logic controller, for example, for the memory unit 106B2, and may include circuitry that manages communication between different components of the bonded structure 100B. The interface logic can include input/output (I/O) interfaces, protocol converters, and other logic circuits that facilitate data transfer and communication to enable the connecting element 102B to facilitate communication between the processor dies 104B1, 104B2 and the memory units 106B1, 106B2. The test pad may correspond to designated areas on the connecting element 102B that provide access points for testing and debugging. The test pad can be used for electrical testing, signal integrity analysis, and other diagnostic purposes associated with the bonded structure 100B.

As noted above, in some examples, the connecting element 102B may comprise a RDL. More specifically, the conductor 124B may be embedded in the RDL. In some examples, the via 108B1 is a TSV. In these examples, the conductor 126B may be connected to the via 108B1 to facilitate communication between the memory unit 106B1 and the processor die 104B1. The connecting element 102B may be hybrid bonded to the processor dies 104B1, 104B2. The memory units 106B1, 106B2 may be hybrid bonded to the connecting element 102B. It should be noted that, in addition to the memory units 106B1 and 106B2, multiple memory units or memory stacks along with I/O interface blocks (not illustrated in FIG. 1C) can be integrated into the bonded structure 100B. Further, in some embodiments, the memory unit 106B1 can communicate with the memory unit 106B2 through the vias 108B1, the vias 108B2, the conductor 126B, the conductor 124B, and/or the conductor 122B.

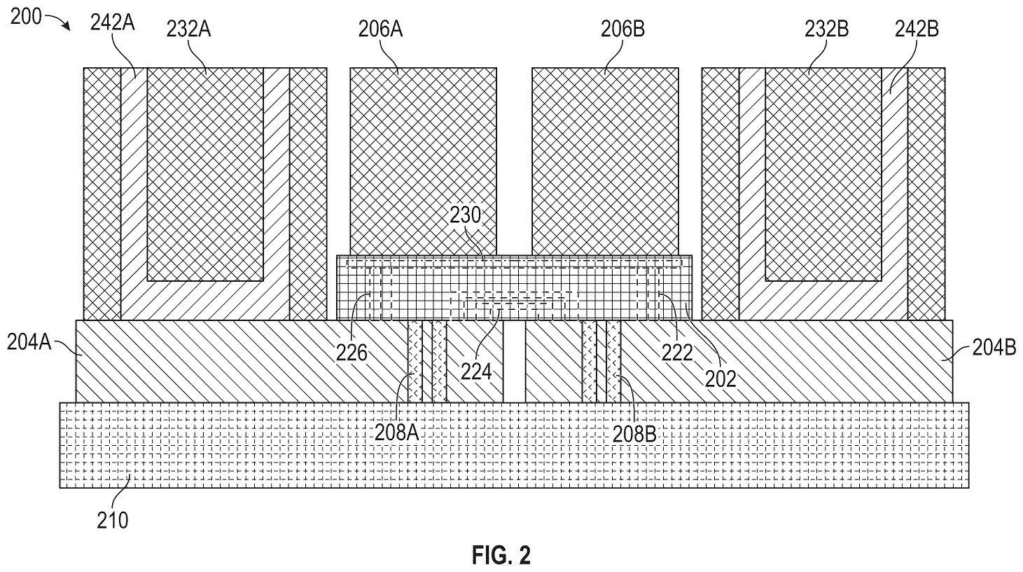

FIG. 2 illustrates a side schematic sectional view of a bonded structure 200 with high bandwidth memories stacked above processor dies according to some embodiments. Unless otherwise noted, the components of FIG. 2 can be the same as or generally similar to like-numbered components of FIG. 1B. As illustrated in FIG. 2, the bonded structure 200 can include a substrate 210, similar to any of the substrates mentioned above, processor dies 204A, 204B mounted to the substrate 210, a connecting element 202, memory units 206A, 206B, and cooling elements 232A, 232B. The processor die 204A includes a via 208A. The processor die 204B includes a via 208B. The connecting element 202 includes conductors 222, 224, 226, 230. The one or more cooling elements can facilitate passive cooling (e.g. dummy dies) or liquid cooling and can also be bonded to the exposed portions of the processor dies 304A and 304B.

In some examples, the conductor 224 electrically connects the processor dies 204A, 204B. The conductors 222, 224, 226, 230 may provide electrical connections to facilitate communication between the processor dies 204A, 204B, and the memory units 206A, 206B. The conductor 230 may be routed in one or more RDLs of the connecting element 202. The vias 208A, 208B may provide electrical connections that facilitate data transfer within the processor dies 204A, 204B, and between the processor dies 204A, 204B and other components of the bonded structure 200.

As shown in FIG. 2, the bonded structure 200 includes the cooling element 232A disposed above the processor die 204A, and the cooling element 232B disposed above the processor die 204B. The cooling elements 232A, 232B may dissipate heat generated by the processor dies 204A, 204B, respectively. For example, the cooling elements 232A, 232B may allow fluid to pass through to thermally manage the processor dies 204A, 204B for avoiding occurrence of overheating conditions. More specifically, the bonded structure 200 may include a liquid channel 242A that is disposed around or in the cooling element 232A, and a liquid channel 242B that is disposed around or in the cooling element 232B. The cooling elements 232A, 232B can be bonded to the hottest components (e.g., the processor dies 204A, 204B) of the bonded structure 200 without increasing a footprint or a height of the bonded structure 200. For example, the cooling elements 232A, 232B can be sized to fit over a current footprint of the processor dies 204A, 204B, respectively. The cooling elements 232A, 232B can have a height approximating an overall height of the connecting element 202 and the memory unit 206A (or the memory unit 206B) such that the footprint or the height of the bonded structure 200 may not increase. In some embodiments, the cooling elements 232A and 232B (e.g. Si die, glass, etc.) are respectively direct bonded to the processor dies 204A and 204B without an adhesive. It should be noted that, in some embodiments, the memory unit 206A can communicate with the memory unit 206B through the vias 208A, the vias 208B, the conductor 224, the conductor 226, and/or the conductor 222.

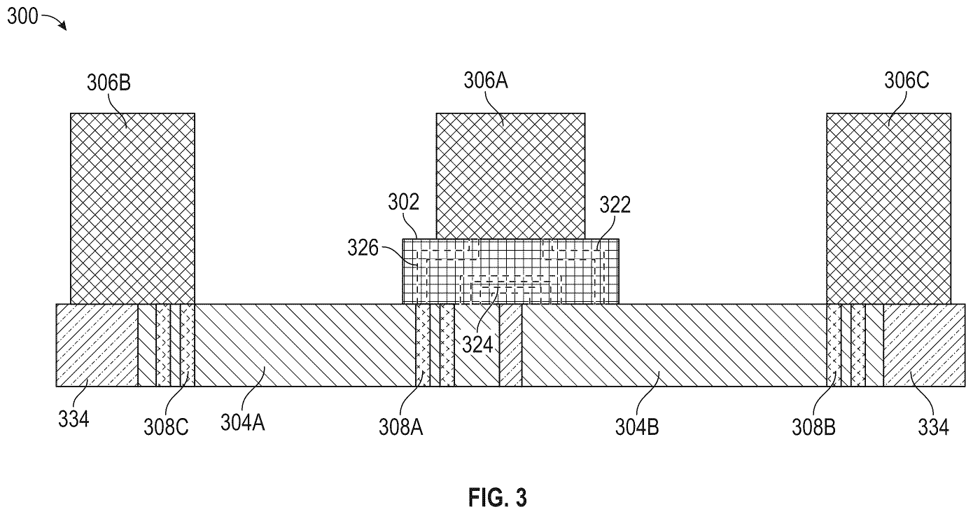

FIG. 3 illustrates a side schematic sectional view of a bonded structure 300 with high bandwidth memories stacked above processor dies according to some embodiments. Unless otherwise noted, the components of FIG. 3 can be the same as or generally similar to like-numbered components of FIGS. 1B-2. As illustrated in FIG. 3, the bonded structure 300 can include processor dies 304A, 304B, a connecting element 302, memory units 306A, 306B, 306C, and a substrate 334. The processor die 304A includes vias 308A, 308C, and the processor die 304B includes a via 308B. The connecting element 302 includes conductors 322, 324, 326. It should be noted that in some examples, the vias 308A, 308C may completely go through the processor die 304A vertically, and/or that the via 308B may completely go through the processor die 304B vertically. In other examples, the vias 308A, 308C may partially go through the processor die 304A vertically, and/or the via 308B may partially go through the processor die 304B vertically. Similarly, the vias within the processor dies (e.g., the via 108B2) shown in FIGS. 1B, 2, 4, 5, 6, and 7 may completely go through or partially go through the associated processor dies (e.g., the processor die 104B2).

As shown in FIG. 3, the conductor 322 can electrically connect the memory unit 306A and the processor die 304B to facilitate data communication between the memory unit 306A and the processor die 304B. The conductor 324 can electrically connect the processor dies 304A, 304B to facilitate data communication between the processor dies 304A, 304B. The conductor 326 can electrically connect the memory unit 306A and the processor die 304A to facilitate data communication between the memory unit 306A and the processor die 304A. The memory unit 306A may be disposed above a center of a monolithic processor formed by the processor dies 304A, 304B. HBM directly stacked near the center of a large monolithic processor can significantly reduce latency and improve performance by providing low latency memory access to the processing cores located near the interior portions of the chip. Although one memory unit 306A is shown, more than one such memory units can also be mounted on the connecting element 302 in an array format.

The bonded structure 300 can further include the memory units 306B, 306C that are respectively disposed above periphery (rather than around the center) of the monolithic processor formed by the processor dies 304A, 304B. As shown in FIG. 3, the memory unit 306B is disposed above the processor die 304A and the substrate 334. The memory unit 306C is disposed above the processor die 304B and the substrate 334. Advantageously, disposing memory units 306B, 306C above periphery of the monolithic processor besides disposing the memory unit 306A above a center of the monolithic processor may increase bandwidth memory as it multiplies (e.g. doubles, triples, etc.) the number of memory units that can be interfaced with the processor chiplets. In some embodiments, the substrate 334, the processor die 304A, and/or the processor die 304B may be reconstituted. More specifically, the substrate 334, the processor die 304A, and/or the processor die 304B may be embedded in an encapsulant. One or more RDL layers can be formed on the reconstituted or embedded dies. The encapsulant can comprise one or multiple inorganic dielectric layers (e.g., silicon oxide, silicon nitride, or the like). In some implementations, the one or more inorganic layers can comprise a first thin conformal layer (e.g., silicon nitride) and a second filling layer (e.g., silicon oxide). In other implementations, the encapsulant can comprise one or multiple organic layers (e.g., molding compound, resin, epoxy, or the like), with a bondable surface on top (e.g., an inorganic dielectric disposed on the organic layer(s)). Although not shown in FIG. 3, one or more passive (e.g. dummy dies) or liquid cooling elements can also be bonded to the exposed portions of the processor dies 304A and 304B.

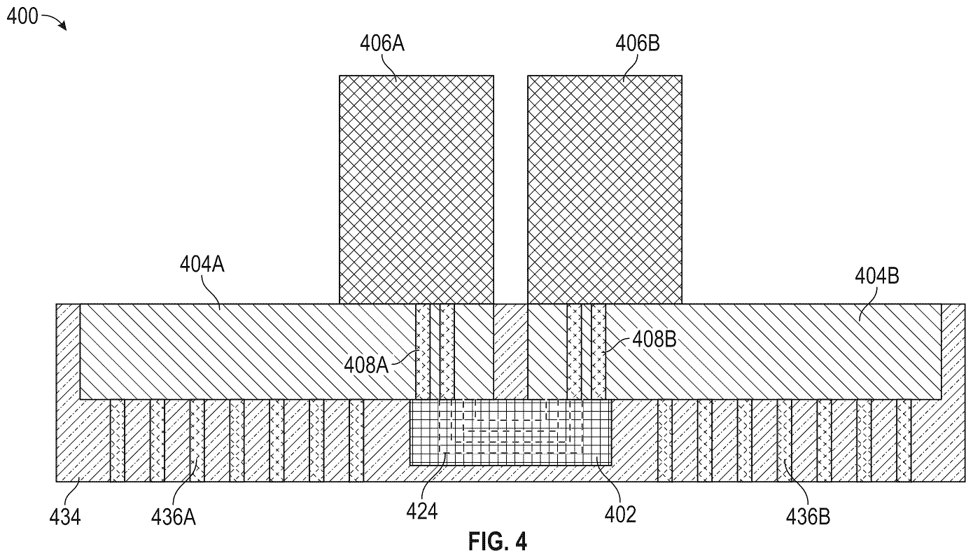

FIG. 4 illustrates a side schematic sectional view of a bonded structure 400 with high bandwidth memories stacked above processor dies according to some embodiments. Unless otherwise noted, the components of FIG. 4 can be the same as or generally similar to like-numbered components of FIGS. 1B-3. As illustrated in FIG. 4, the bonded structure 400 can include processor dies 404A, 404B, a connecting element 402, memory units 406A, 406B, and a substrate 434. The processor die 404A includes a via 408A, and the processor die 404B includes a via 408B. The connecting element 302 includes a conductor 424. The connecting element 302 can also include through substrate vias (not shown). The substrate 434 includes vias 436A, 436B. The substrate 434, the processor die 404A, and/or the processor die 404B may be reconstituted. In some embodiments, the processor die 404A, and/or the processor die 404B may be reconstituted in one or more dielectric materials (e.g. organic or inorganic materials/layers) to form the substrate 434. The via 436A can include any number of input/output connections for connecting the processor die 404A to the substrate 434. The via 436B can include any number of input/output connections for connecting the processor die 404B to the substrate 434. It should be noted that in some examples, one or both of the vias 436A, 436B may completely go through the substrate 434 vertically. In other examples, one or both of the vias 436A, 436B may partially go through the substrate 434 vertically. Although not shown in FIG. 4, one or more passive elements (e.g. dummy dies) or liquid cooling elements can also be bonded to the exposed portions of the processor dies 304A and 304B.

In some examples, as shown in FIG. 4, the processor die 404B is laterally separated from the processor die 404A by the reconstitution dielectric material(s). The memory unit 406A is disposed vertically above the processor die 404A. The connecting element 402 is disposed vertically to (e.g., below) the processor dies 404A, 404B. As such, the processor dies 404A, 404B are vertically between the connecting element 402 and the memory unit 406A (or the memory unit 406B) in these examples. The connecting element 402 includes the conductor 424 that electrically connects the processor dies 404A, 404B. In some examples, the processor die 404B may communicate with the memory unit 406A at least through the via 408A and the conductor 424. The processor die 404A may communicate with the memory unit 406B at least through the via 408B and the conductor 424. In some embodiments, the memory unit 406A can also communicate with the memory unit 406B through the vias 408A and 408B and the conductor 424.

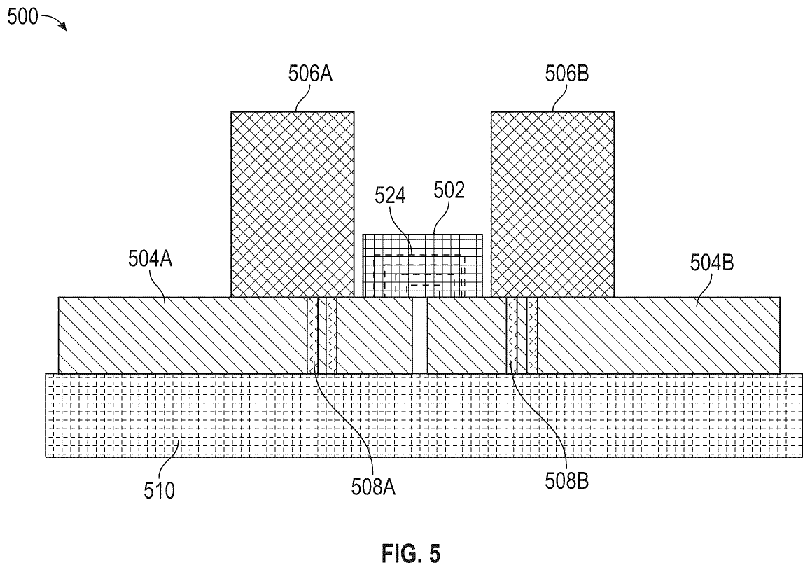

FIG. 5 illustrates a side schematic sectional view of a bonded structure 500 with high bandwidth memories stacked above processor dies according to some embodiments. Unless otherwise noted, the components of FIG. 5 can be the same as or generally similar to like-numbered components of FIGS. 1B-4. As illustrated in FIG. 5, the bonded structure 500 can include processor dies 504A, 504B, a connecting element 502, memory units 506A, 506B, and a substrate 510. The processor die 504A includes a via 508A, and the processor die 504B includes a via 508B. The connecting element 502 includes a conductor 524. Although FIG. 5 shows the vias 508A and 508B in the processor dies to be under the shadow of memory units 506A and 506B respectively, similar vias may also be formed under the shadow of the connecting element 502.

As shown in FIG. 5, the connecting element 502 may be disposed vertically above the processor dies 504A, 504B. Further, the connecting element 502 may be disposed laterally between the memory units 506A, 506B. In some examples, the conductor 524 of the connecting element 502 can electrically connect the processor dies 504A, 504B. In some other embodiments, processor die 504A can communicate to memory unit 506B using vias 508A and conductor 524 in the connecting element 502. In some embodiments, one or more RDLs can be formed on the processor dies (e.g. when processor dies are reconstituted). In some other embodiments, memory unit 506A can communicate to memory unit 506B using such RDL and conductor 524 in the connecting element 502. Compared with the bonded structure 100B of FIG. 1B, the memory units 506A, 506B of FIG. 5 can be mounted (e.g., directly bonded) directly to the processor dies 504A, 504B respectively, as opposed to being mounted on a connecting element (e.g., the connecting element 102B). In some examples, the processor dies 504A and 504B are bonded face down over the substrate 510. In these examples, the front active side (e.g., the side nearest active circuitry or transistors) may face down. The processor dies 504A and 504B may electrically communicate to the memory units 506A and 506B through the TSVs 508A and 508B, respectively. In other examples, the processor dies 504A and/or 504B may be bonded face up over the substrate 510. In these examples, the front active side (e.g., the side nearest active circuitry or transistors) may face up. The memory unit 506A and 506B may be bonded on the front side of the processor dies 504A and 504B. The processor dies 504A and 504B may electrically communicate to the substrate 510 via the TSVs 508A and 508B, or via a backside RDL layer (not shown) formed on the backsides of the processor dies 504A and 504B. In some embodiments, backside RDL is formed on the processor dies 504A and 504B to provide power from backside of the die. For example, backside power delivery network (BS-PDN) is formed at the back of the processor dies and power is delivered into BS-PDN of the die via backside RDL.

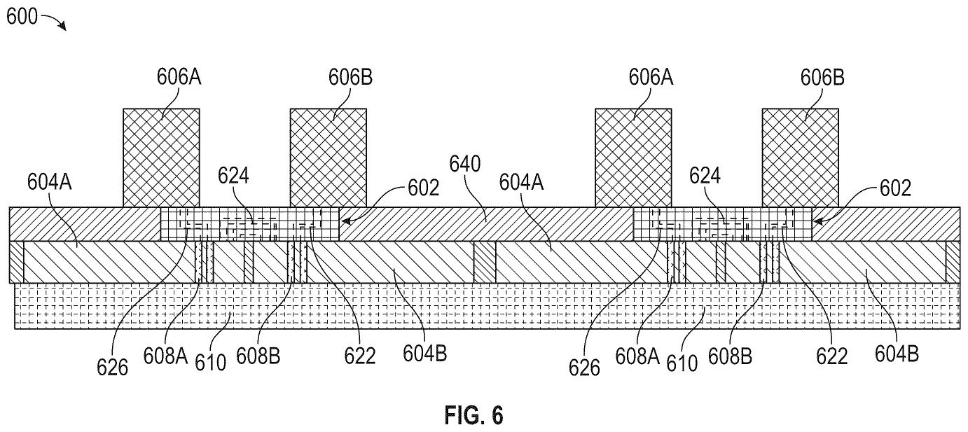

FIG. 6 illustrates a side schematic sectional view of a bonded structure 600 with high bandwidth memories stacked above processor dies according to some embodiments. Unless otherwise noted, the components of FIG. 6 can be the same as or generally similar to like-numbered components of FIGS. 1B-5. As illustrated in FIG. 6, the bonded structure 600 can include processor dies 604A, 604B, connecting elements 602, memory units 606A, 606B, a substrate 610, and a reconstituted layer 640. The processor die 604A includes a via 608A, and the processor die 604B includes a via 608B. The connecting elements 602 include conductors 624, 622, 626.

As shown in FIG. 6, the processor dies 604A, 604B are reconstituted, and at least partially embedded in the reconstituted layer 640. The processor dies 604A, 604B are disposed above the substrate 610. The connecting elements 602 are reconstituted, and at least partially embedded in the reconstituted layer 640. The connecting element 602 are disposed above the processor dies 604A, 604B. In some examples, reconstituted components (e.g., the processor die 604A, the processor die 604B, and/or the connecting elements 602) can comprise one or more dielectrics in which semiconductor dies or devices are embedded.

As illustrated in FIG. 6, a bonding surface for the memory unit 606A or the memory unit 606B to be bonded to the connecting elements 602 and the reconstituted layer 640 can comprise an upper surface of the reconstituted layer 640 and an upper surface of the connecting elements 602; and the connecting elements 602 are exposed at the bonding surface. Alternatively, although not shown in FIG. 6, the connecting elements 602 can be embedded such that a bonding layer (not shown in FIG. 6) can be disposed over the connecting elements 602 and/or the reconstituted layer 640. It should be noted that the processor dies 604A and/or 604B can be reconstituted with or without the bonding layer (or a separate RDL) on top. Further, reconstituted wafers of the connecting elements 602 and processor dies 604A and 604B can be bonded to each other.

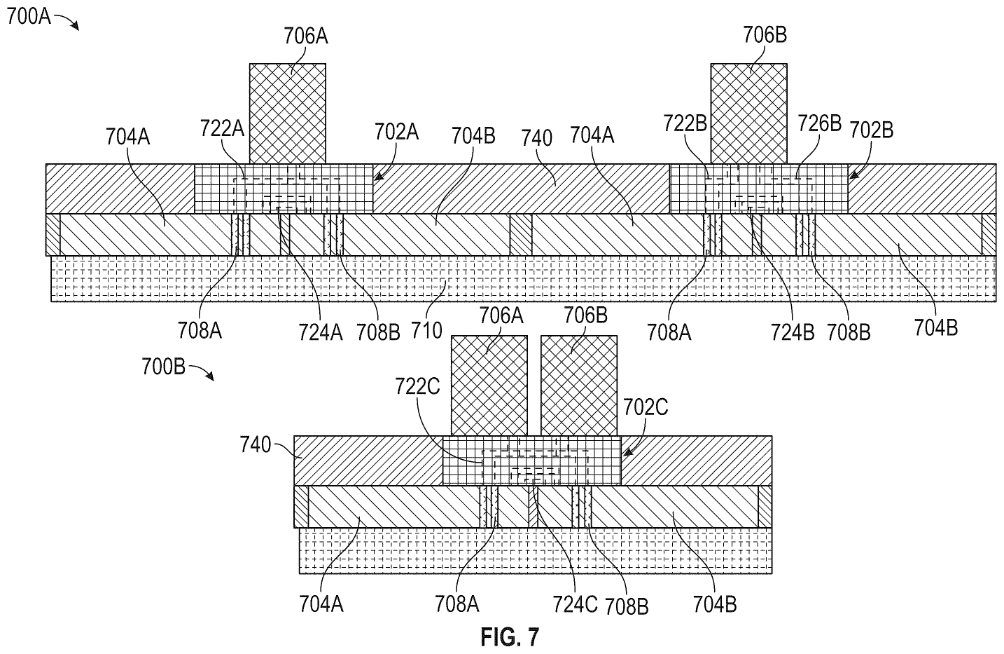

FIG. 7 illustrates a side schematic sectional view of a bonded structures 700A and a bonded structure 700B with high bandwidth memories stacked above processor dies according to some embodiments. Unless otherwise noted, the components of FIG. 7 can be the same as or generally similar to like-numbered components of FIGS. 1B-6. As illustrated in FIG. 7, the bonded structure 700A and the bonded structure 700B can include processor dies 704A, 704B, connecting elements 702A, 702B, 702C, memory units 706A, 706B, a substrate 710, and reconstituted layers 740. The processor die 704A includes a via 708A, and the processor die 704B includes a via 708B. The connecting element 702A includes conductors 722A, 724A. The connecting element 702B includes conductors 722B, 724B, 726B. The connecting element 702C includes conductors 722C, 724C.

FIG. 7 depicts the embodiment where multiple processor dies accesses or shares one memory unit (e.g. HBM) or a set of memory units. As shown in FIG. 7, in some examples, the connecting element 702A enables both the processor dies 704A, 704B to communicate with the same channel of the memory unit 706A at least through the conductor 722A. In some examples, the connecting element 702B enables the processor dies 704A, 704B to communicate with different channels of the memory unit 706B. For example, the processor die 704A may communicate with a first channel of the memory unit 706B through the conductor 722B, and the processor die 704B may communicate with a second channel of the memory unit 706B through the conductor 726B. In some examples, the connecting element 702C enables the processor dies 704A, 704B to communicate with the same channel and different channels of the memory unit 706A and/or the memory unit 706B. For example, the conductor 722C enables the processor dies 704A, 704B to communicate with a first channel of the memory unit 706A, and also enables the processor dies 704A, 704B to communicate with a second channel of the memory unit 706A. As another example, a logic controller (not shown in FIG. 7) associated with the connecting element 702C can control access of the memory unit 706A and the memory unit 706B that are both placed on the connecting element 702C. In some embodiments, the connecting element 702A, 702B, or 702C allows the processor dies 704A and 704B to only access the memory units 706A and/or 706B without communicating with each other.

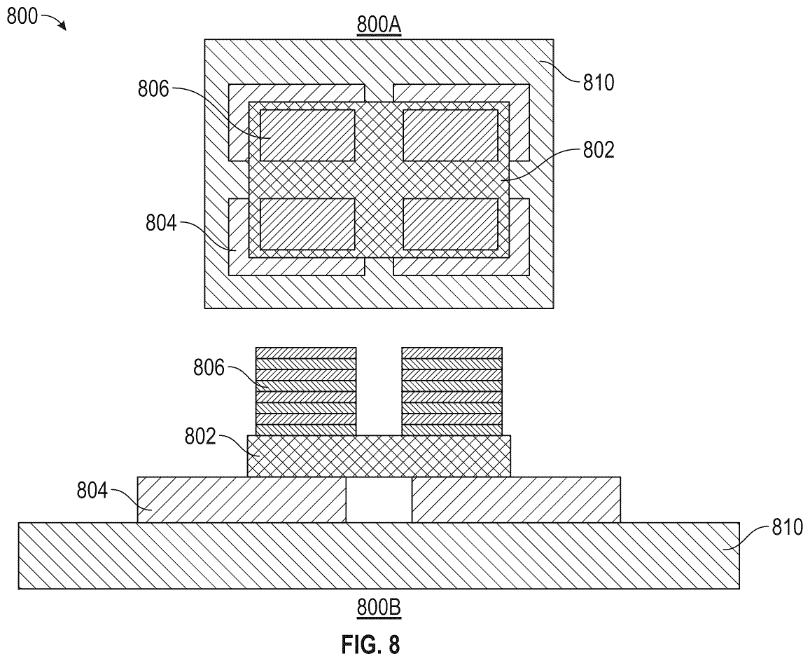

FIG. 8 illustrates a top schematic view 800A and a side schematic sectional view 800B of a bonded structure 800 with high bandwidth memories stacked above processor dies according to some embodiments. Unless otherwise noted, the components of FIG. 8 can be the same as or generally similar to like-numbered components of FIGS. 1B-7. As illustrated in FIG. 8, the bonded structure 800 can include processor dies 804, a connecting element 802, memory units 806, and a substrate 810. The connecting element 802 may facilitate communication between each of the four memory units 806 and each of the four processor dies 804 such that each of the four memory units 806 may communicate with each of the four processor dies 804.

As shown in FIG. 8, the bonded structure 800 includes four processor dies 804 and four memory units 806. The set of processor dies and memory units are arranged in 2×2 arrangement or configuration. It should be noted, however, more or fewer processor dies and memory units in any suitable arrangement may be integrated into the bonded structure 800. In some examples, the processor dies 804 are laterally spaced from each other, and each of the processor dies 804 is disposed above the substrate 810. The memory units 806 may be disposed vertically above the processor dies 804. The memory units 806 may be disposed on the connecting element 802. The connecting element 802 may be disposed vertically between the processor dies 804 and the memory units 806. In some examples, the processor dies 804 may form a monolithic processor (e.g., a GPU, a CPU, a NPU, a TPU, or the like). In some embodiments, the connecting elements 802 may comprise an active interposer with one or more functionalities including but not limited to logic controller for one or more memory units, cache (e.g. L1, L2, L3 cache), network on chip (NOC), switch chip (e.g. network switch), accelerator fabric links, IO interfaces, PCIe express, HBM interface, fuse, photonic IC, optical waveguide, laser, photodiode, etc.).

As noted above, the bonded structure 800 offers several advantages. Latency for data transfer between the processor dies 804 and the memory units 806 may be significantly reduced compared with the implementations of FIG. 1A. For example, instead of connecting the processor die 104A1 and the memory unit 106A1 using lateral conductive traces that may be about 3 mm to 6 mm in length, the processor dies 804 and the memory units 806 may vertically communicate with each other through vertical passthrough traces that may be between 5 μm to 2 mm. As such, latency may be significantly reduced. Additionally, by disposing the memory units 806 above and near a center of a monolithic processor formed by the processor dies 804, low latency memory access for processing cores or interior portions of the monolithic processor can be accomplished. Further, instead of using multiple bridges to facilitate communications between processor dies 804 and memory units 806, the bonded structure 800 can achieve many-to-many communication between the processor dies 804 and the memory units 806 through the connecting element 802, thereby reducing costs and packaging sizes associated with packaging the bonded structure 800. In this configuration, a single processing die can access multiple memory stacks with comparable latency and/or several processing dies can also access or share multiple memory stacks with similar latency. At the same time, several processing dies can interface directly with each other. One controller die can also interface with multiple processing dies and provide access to multiple memory stacks via only one controller die.

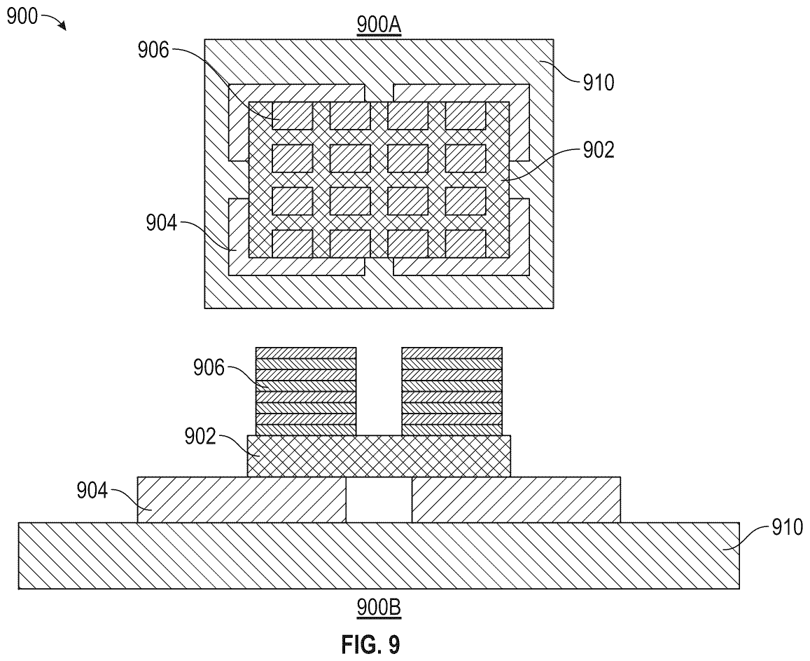

FIG. 9 illustrates a top schematic view 900A and a side schematic sectional view 900B of a bonded structure 900 with high bandwidth memories stacked above processor dies according to some embodiments. Unless otherwise noted, the components of FIG. 9 can be the same as or generally similar to like-numbered components of FIGS. 1B-8. As illustrated in FIG. 9, the bonded structure 900 can include processor dies 904, a connecting element 902, memory units 906, and a substrate 910.

In some examples, the bonded structure 900 may be functionally and/or structurally the same as or similar to the bonded structure 800 except that the bonded structure 900 includes more memory units. More specifically, the bonded structure 900 includes sixteen memory units 906 and four processor dies 904. The connecting element 902 may facilitate communication between each of the sixteen memory units 906 and each of the four processor dies 904 such that each of the sixteen memory units 906 may communicate with each of the four processor dies 904.

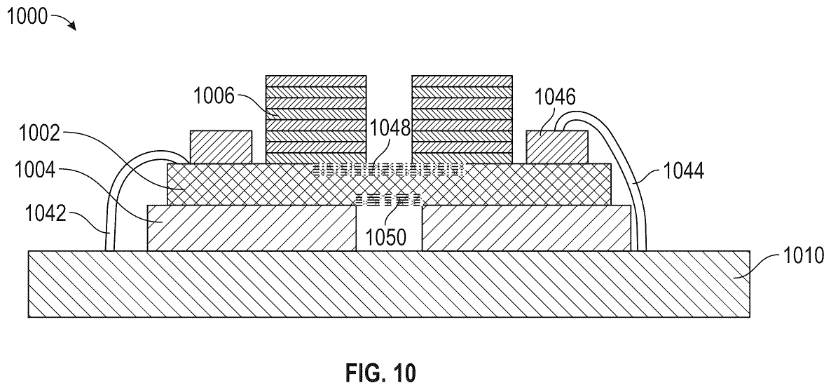

FIG. 10 illustrates a side schematic sectional view of a bonded structure 1000 with high bandwidth memories stacked above processor dies according to some embodiments. Unless otherwise noted, the components of FIG. 10 can be the same as or generally similar to like-numbered components of FIGS. 1B-9. As illustrated in FIG. 10, the bonded structure 1000 can include processor dies 1004, a connecting element 1002, memory units 1006, a substrate 1010, a semiconductor die 1046, and bond wires 1044, 1042. The connecting element 1002 includes conductors 1048, 1050.

In some examples, the conductors 1048, 1050 can be embedded near two sides (e.g., a bottom side and a top side) of the connecting element 1002. For example, the conductor 1048 may be embedded in a RDL of the connecting element 1002, and the conductor 1050 may be embedded in another RDL of the connecting element 1002. The conductors 1048, 1050 can enable each of the processor dies 1004 to communicate with each of the memory units 1006.

As shown in FIG. 10, the bonded structure 1000 can include a bond wire 1044, as an additional connectivity option, that electrically connects the semiconductor die 1046 to the substrate 1010. It should be noted additional semiconductor die(s) can also be bonded to the connecting element 1002 if the connecting element 1002 is wide enough to accommodate the additional semiconductor die(s). As may be appreciated, the connecting element 1002 can be widened rather inexpensively, in particular when the connecting element 1002 is a passive or dummy interconnect. The bonded structure 1000 can also include the bond wire 1042 that electrically connects the connecting element 1002 to the substrate 1010. FIG. 10 shows that the memory units 1006 and the semiconductor die 1046 are disposed on the connecting element 1002. In some examples, the connecting element 1002 can be hybrid bonded to the processor dies 1004. The memory units 1006 and the semiconductor die 1046 can be hybrid bonded to the connecting element 1002. The connecting element 1002 may comprise test pads (not shown) to test the electrical yield of the bonded structure 1000.

### Example Assembly Processes

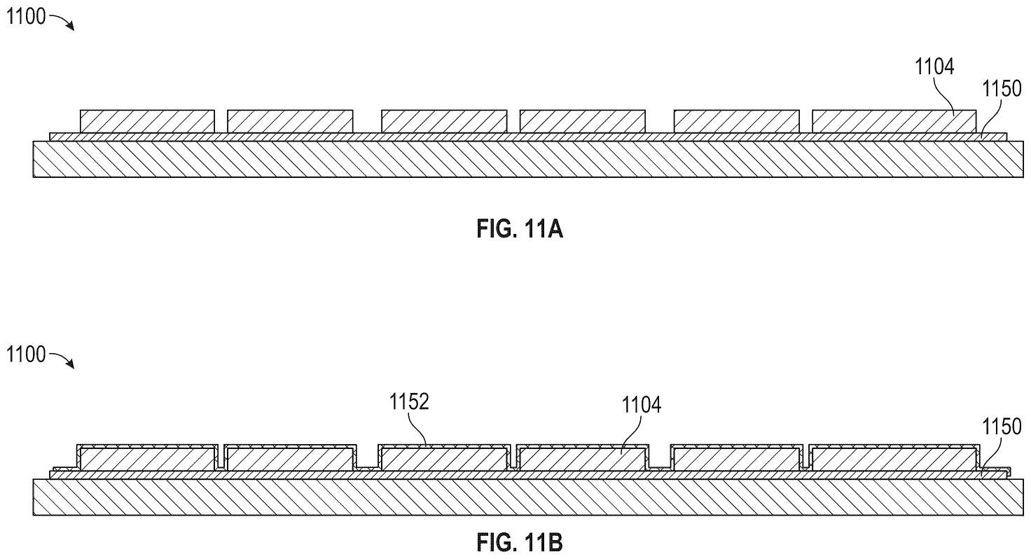

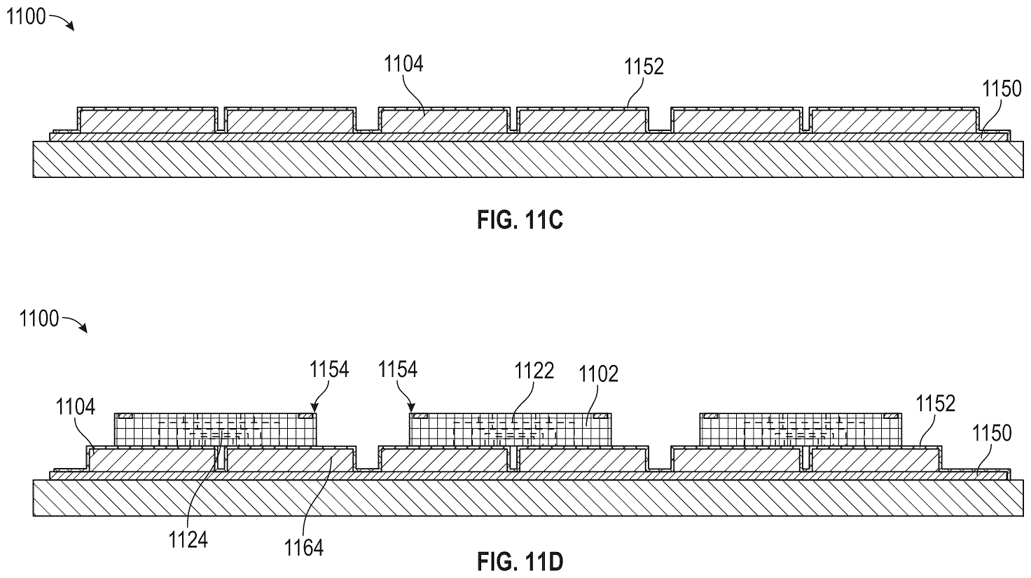

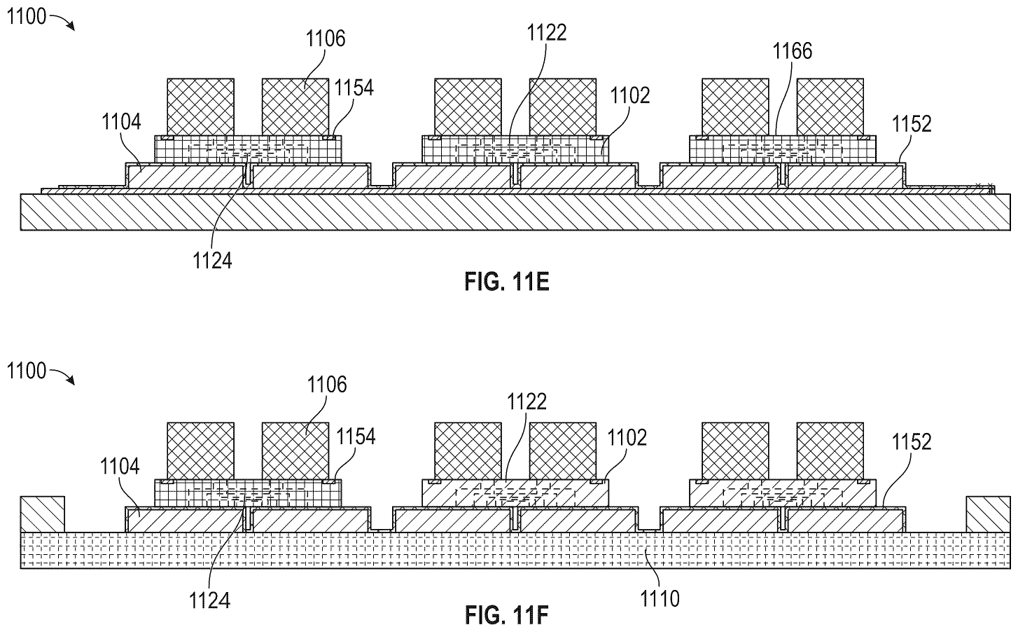

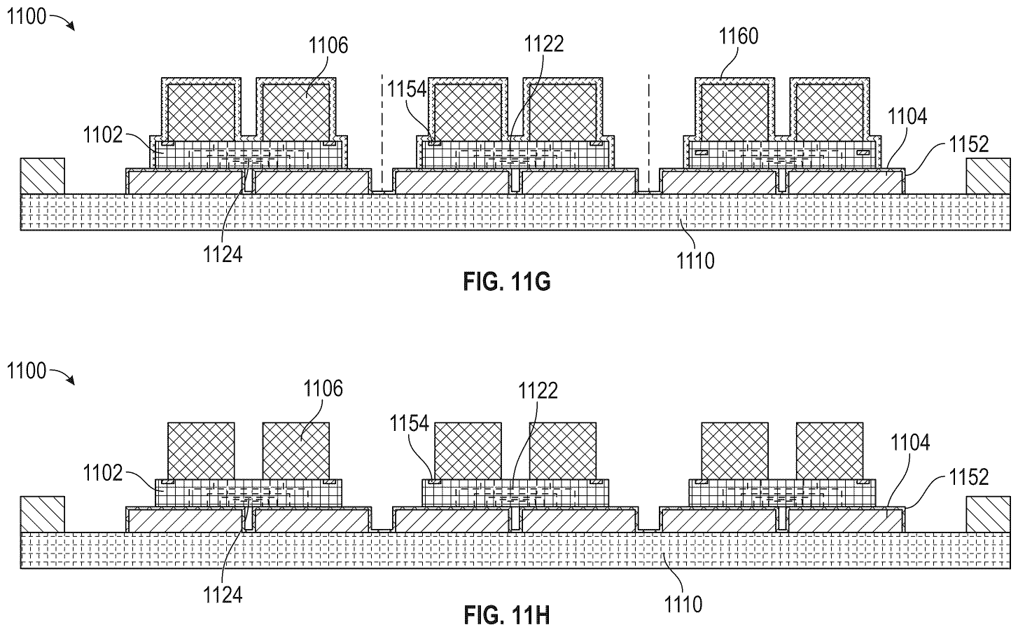

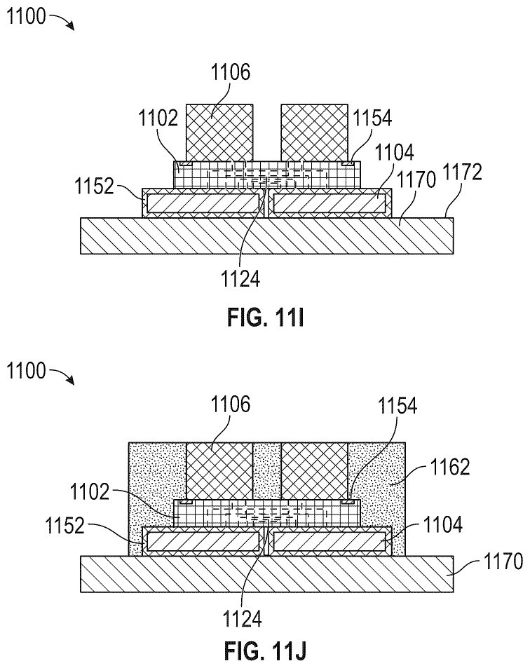

FIGS. 11A-11J illustrate an example process for assembling a bonded structure 1100 according to some embodiments. The bonded structure 1100 can be structurally the same as or similar to at least some of the bonded structures 100B, 200, 300, 400, 500, 600, 700, 800, 900, and 1000. As shown in FIG. 11A, processor dies 1104 can be bonded to a temporary support layer 1150, which may serve as a substrate or a carrier. The temporary support layer 1150 may provide structural stability during subsequent assembly steps of the process. The processor dies 1104 can be bonded and secured on the temporary support layer 1150, and can be prepared for further processing and integration with other components (e.g., connecting elements and memory units that will be described later) in the bonded structure 1100.

As shown in FIG. 11B, one or more dielectric layers 1152 can be coated over the processor dies 1104 and the temporary support layer 1150. The dielectric layer 1152 can serve several purposes, such as providing electrical insulation, mechanical stability, and protection for the processor dies 1104. Here, the dielectric layer 1152 can be a conformal dielectric coating. It should be noted that, in some examples, the dielectric layer 1152 can be inorganic material, such as silicon oxide, silicon nitride, or the like. In some examples, the dielectric layer 1152 may be coated to uniformly cover the processor dies 1104 and the temporary support layer 1150, preparing the structure for subsequent steps in the process, such as planarization, bonding of connecting elements, and integration of memory units. In some embodiments, the dielectric layer 1152 may comprise a molding layer, the molding layer at least partially encapsulating the processor dies 1104.

FIG. 11C illustrates that the dielectric layer 1152 can be planarized for further processing. For example, planarizing the dielectric layer 1152 may expose contact pads (not shown) (e.g., contact pads that were already exposed before the dielectric layer 1152 is deposited or protruding above the surface of the processor dies 1104) on a backside of the processor dies 1104 that are bonded to the temporary support layer 1150. Advantageously, planarizing the dielectric layer 1152 may ensure that the contact pads are accessible for subsequent assembly processes. Planarizing the dielectric layer 1152 may also provide a smooth and even surface on the dielectric layer 1152, facilitating the integration of connecting elements and memory units for subsequent steps of the process.

FIG. 11D illustrates that connecting elements 1102 can be bonded to the processor dies 1104. In some examples, the connecting elements 1102 may be bonded to the processor dies 1104 using hybrid bonding to ensure that the connecting elements 1102 to securely attach the connecting elements 1102 to the processor dies 1104 at a fine pitch. As noted above, the connecting elements 1102 may facilitate electrical communication between the processor dies 1104 and other components, such as memory units, that will be integrated in subsequent steps. More specifically, the connecting elements 1102 may facilitate electrical communication between the processor dies 1104 and memory units to be integrated (e.g., through conductors 1122, 1124 that may be routed in one or more layers of the connecting elements 1102). The connecting elements 1102 may further include test pads 1154 that can be used for electrical testing, signal integrity analysis, and other diagnostic purposes associated with the bonded structure 1100.

Although not explicitly illustrated in FIG. 11D, a backside 1164 of the processor die 1104 can be activated and the connecting element 1102 can be hybrid bonded to the backside 1164 of the processor dies 1104, after the backside 1164 is activated. In some examples, the bonded structure 1100 may be annealed at low temperature such that bonding between the connecting elements 1102 and the processor dies 1104 may be strengthened and to connect opposing conductive contact features. In some embodiments, the connecting element 1102 may comprise a reconstituted layer reconstituted over the processor die 1104.

FIG. 11E illustrates that memory units 1106 are bonded (e.g., hybrid bonded) to the connecting elements 1102. The memory units 1106 can be stacked vertically above the processor dies 1104, with the connecting elements 1102 facilitating electrical communication between the processor dies 1104 and the memory units 1106. As noted above, the integration of memory units 1106 as shown in FIG. 11E may reduce memory latency and increase memory bandwidth associated with the processor dies 1104 by utilizing vertical passthrough connections provided by the conductor 1122 and/or the conductor 1124.

Although not explicitly illustrated in FIG. 11E, a backside 1166 of the connecting element 1102 can be activated and the memory units 1106 can be hybrid bonded to the backside 1166 of the connecting element 1102, after the backside 1166 is activated. In some examples, the bonded structure 1100 may be annealed at temperatures ranging between 100 to 350° C. and preferably between 180 to 300° C., such that bonding between the connecting elements 1102 and the memory units 1106 may be strengthened and to connect opposing conductive contact features. The annealing time may range from 30 minutes to over 360 minutes, and preferably between 60 minutes to 180 minutes. In practice, the higher the temperature the shorter the annealing time, and vice versa. In some embodiments, as a consequence of the bonded structures having varying coefficients of thermal expansion, it may be desirable to heat and cool the assembled structure at heating and cooling rate less than 40° C. per minute, less than 20° C. per minute, or less than 10° C. per minute. After annealing and testing the bonded structure 1100, the bonded structure 1100 may be encapsulated with a suitable polymeric layer such as a molding compound with low coefficient of thermal expansion (CTE), with CTE preferably less than 20 ppm/° C. The unwanted portion of the molding compound may be removed by planarization methods. The molded bonded structure 1100 (not shown) is removed from the temporary support layer 1150 for subsequent processing.

FIG. 11F illustrates that the bonded structure 1100 may be mounted on a frame for singulation. As shown in FIG. 11F, the processor dies 1104, the connecting elements 1102, and the memory units 1106 are mounted on a substrate 1110 to prepare the bonded structure 1100 to be singulated in subsequent steps.

FIG. 11G illustrates that the bonded structure 1100 is coated with a protective layer 1160 for singulation as indicated by the dash lines. The protective layer 1160 can protect the underlying components, such as the processor dies 1104, the connecting elements 1102, and the memory units 1106, from physical damage and contamination during the singulation process. The protective layer 1160 can be made of various materials, such as an organic dielectric including an organic resist layer. In some embodiments, the bonded structure 1100 may be tested and molded and unwanted portion of the mold layer removed by planarization methods prior to the singulation step.

FIG. 11H illustrates that the protective layer 1160 is stripped from the bonded structure 1100, and the bonded structure 1100 that has been singulated as shown in FIG. 11G is cleaned and dried. More specifically, as shown in FIG. 11H, after the protective layer 1160 is removed or stripped from the bonded structure 1100, the bonded structure 1100, which has been singulated, may undergo a cleaning and drying process. The cleaning and the drying on the bonded structure 1100 may ensure that any residues or contaminants from the protective layer 1160 are eliminated, and the bonded structure 1100 is prepared for subsequent integration into larger systems. The protective layer removal process may comprise stripping the protective layer 1160 with the suitable solvent by, for example, rinsing the singulated bonded structure 1100 with deionized water (DI) or other suitable fluid, and drying the cleaned and rinsed singulated bonded structure 1100. The drying step may comprise spin drying the structure 1100 at a suitable RPM (revolutions per minute), or other know drying methods.

FIG. 11I illustrates that the bonded structure 1100 that has been cleaned and/or dried as illustrated in FIG. 11H is bonded to a substrate 1170. Although not explicitly illustrated in FIG. 11I, before the bonded structure 1100 is bonded to the substrate 1170, a surface 1172 of the substrate 1170 may be cleaned and activated. In some examples, cleaning the surface 1172 of the substrate 1170 may include removing any contaminants, residues, or particles that could interfere with bonding the processor dies 1104 to the substrate 1170. Activating the surface 1172 of the substrate 1170 may involve treating the surface 1172 with a plasma or chemical process to enhance its bonding properties, thereby ensuring a strong and reliable bond between the processor dies and the substrate 1170 to achieve better or optimal electrical and mechanical performance of the bonded structure 1100.

FIG. 11J illustrates that the bonded structure 1100 is encapsulated with an encapsulant 1162. In some examples, the molding process involves at least partially encapsulating the bonded structure 1100, which includes the processor dies 1104, the connecting elements 1102, and the memory units 1106, with the encapsulant 1162. The encapsulant 1162 can be an organic dielectric, such as a polymeric molding compound, or an inorganic dielectric, such as silicon oxide or silicon nitride. The encapsulant 1162 may provide mechanical stability, environmental protection, and electrical insulation to the bonded structure 1100. By using the encapsulant 1162 to encapsulate the bonded structure 1100, the encapsulant 1162 helps to protect the processor dies 1104, the connecting elements 1102, and the memory units 1106 from physical damage, contamination, and moisture, ensuring the integrity and reliability of the bonded structure 1100 during handling, testing, and operation. In some embodiments, the unwanted portion of the encapsulant 1162 may be removed by planarization methods.

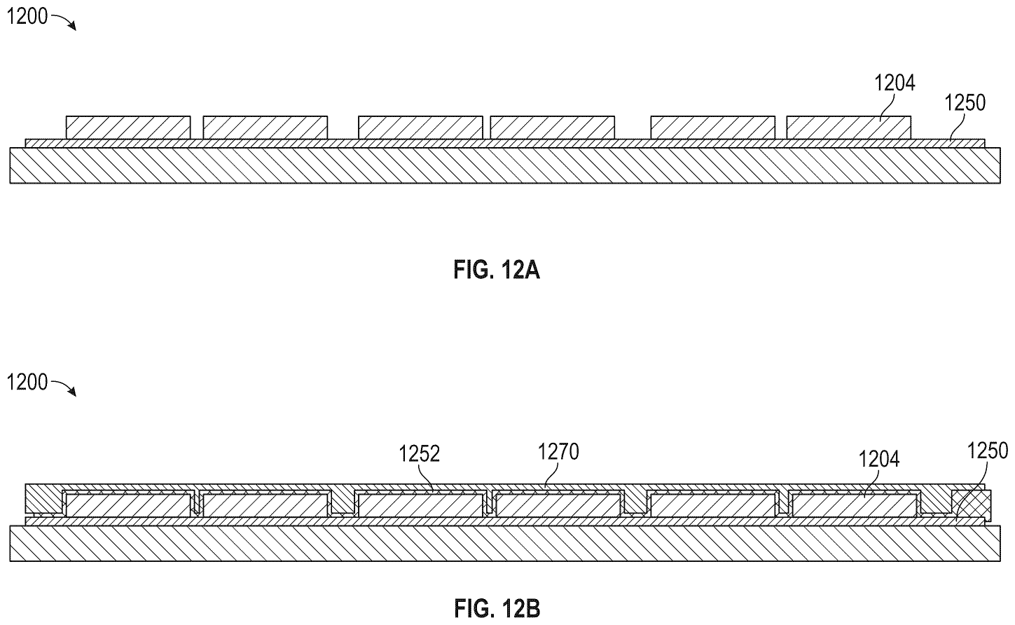

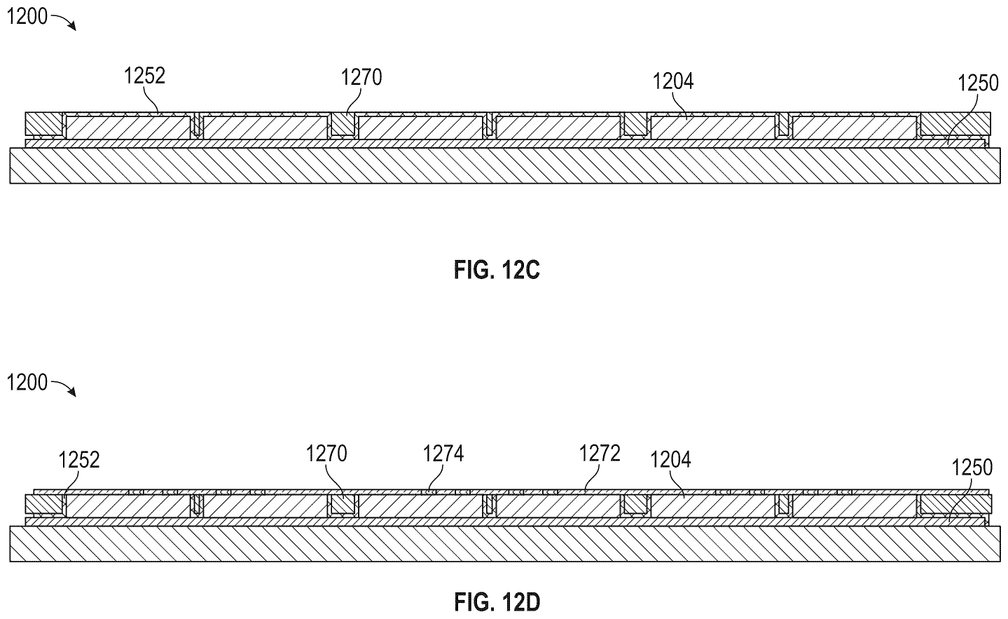

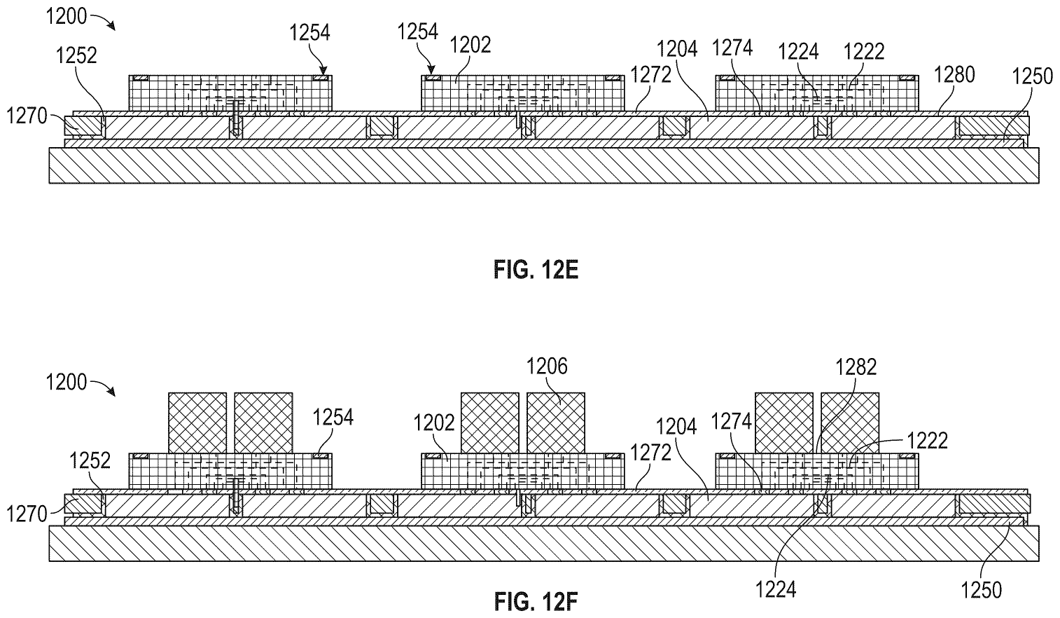

FIGS. 12A-12F illustrate an example process for assembling a bonded structure 1200 according to some embodiments. The bonded structure 1200 can be structurally the same as or similar to at least some of the bonded structures 100B, 200, 300, 400, 500, 600, 700, 800, 900, and 1000. As shown in FIG. 12A, processor dies 1204 can be bonded (e.g. direct bonded) to a temporary support layer 1250, which may serve as a substrate or a carrier. The temporary support layer 1250 may provide structural stability during subsequent assembly steps of the process. The processor dies 1204 can be bonded and secured on the temporary support layer 1250, and can be prepared for further processing and integration with other components (e.g., connecting elements and memory units that will be described later) in the bonded structure 1200.

As shown in FIG. 12B, a dielectric layer 1252 and a dielectric layer 1270 can be coated over the processor dies 1204 and the temporary support layer 1250. Dielectric layers 1252 and/or 1270 can comprise one or more materials or one or more layers of dielectrics. The dielectric layer 1252 and the dielectric layer 1270 can serve several purposes, such as filling spaces between the processor dies 1204, providing electrical insulation, mechanical stability, and protection for the processor dies 1204. In some examples, the dielectric layer 1252 and the dielectric layer 1270 may be coated to uniformly cover the processor dies 1204 and the temporary support layer 1250, preparing the structure for subsequent steps in the process, such as planarization, bonding of connecting elements, and integration of memory units.

FIG. 12C illustrates that the dielectric layer 1252 and/or the dielectric layer 1270 can be planarized for further processing. For example, planarizing the dielectric layer 1252 and/or the dielectric layer 1270 may expose contact pads (not shown) in a via reveal process on a backside of the processor dies 1204 that are bonded to the temporary support layer 1250. Advantageously, planarizing the dielectric layer 1252 may ensure that the contact pads are accessible for subsequent assembly processes. Planarizing the dielectric layer 1252 and/or the dielectric layer 1270 may provide a smooth and even surface on the dielectric layer 1252 and/or the dielectric layer 1270, facilitating the integration of connecting elements and memory units for subsequent steps of the process.

FIG. 12D illustrates that a bonding layer 1272 is formed over the dielectric layer 1252 and the dielectric layer 1270 that are planarized in FIG. 12C. Besides forming the bonding layer 1272, conductive contact pads 1274 may be formed within an RDL layer (not shown in FIG. 12D) associated with the bonding layer 1272. In some examples, the conductive contact pads 1274 may be in electrical contact with TSVs (not shown) revealed on a backside of the processor die 1204. In other examples, the bonding layer 1272 can include the dielectric layer 1270 and the conductive contact pads 1274 can be embedded within the bonding layer 1272.

FIG. 12E illustrates that connecting elements 1202 can be bonded to the processor dies 1204 and the bonding layer 1272. In some examples, the connecting elements 1202 may be bonded to the processor dies 1204 and the bonding layer 1272 using hybrid bonding to ensure that the connecting elements 1202 to securely attach the connecting elements 1202 to the bonding layer 1272, which is electrically connected to the processor dies 1204. As noted above, the connecting elements 1202 may facilitate electrical communication between the processor dies 1204 and other components, such as memory units, that will be integrated in subsequent steps. As shown in FIG. 12E, the connecting elements 1202 can also include test pads 1254. In some embodiments, the connecting elements 1202 may be formed over the backside of the processor die 1204. In some embodiments, connecting elements 1202 can be reconstituted on the underlying layer of the processor dies 1204.

Although not explicitly illustrated in FIG. 12E, a backside 1280 of the processor die 1204 can be activated and the connecting element 1202 can be hybrid bonded to the backside 1280 of the processor die 1204, after the backside 1280 has been activated. In some examples, the bonded structure 1200 may be annealed at low temperature such that bonding between the connecting elements 1202 and the processor dies 1204 (e.g., the backside 1280 of the processor die 1204) may be strengthened.

FIG. 12F illustrates that memory units 1206 are bonded (e.g., hybrid bonded) to the connecting elements 1202. The memory units 1206 can be stacked vertically above the processor dies 1204, with the connecting elements 1202 facilitating electrical communication between the processor dies 1204 and the memory units 1206. As noted above, the integration of memory units 1206 as shown in FIG. 12F may reduce memory latency and increase memory bandwidth associated with the processor dies 1204 by utilizing vertical passthrough connections provided by the conductor 1222 and/or the conductor 1224.

Although not explicitly illustrated in FIG. 12F, a backside 1282 of the connecting element 1202 can be activated and the memory units 1206 can be hybrid bonded to the backside 1282 of the connecting element 1102, after the backside 1282 has been activated. In some examples, the bonded structure 1200 may be annealed at a higher temperature such that bonding between the connecting elements 1202 and the memory units 1206 may be strengthened.

In some embodiments, processor dies 1204 are reconstituted on a carrier wafer (e.g. as shown in FIG. 12A-D). One or more layers of RDL (not shown in FIG. 12F) can be formed at a backside of the processor dies 1204 so as to create high density wiring between the processor dies 1204 as well as vias and routing, thereby enabling the connection between the memory units 1206. A separate bonding layer (not shown in FIG. 12F) can be formed with hybrid bondable contacts exposed at the top or above the processor dies 1204. Memory units 1206 can be bonded to the bonding layer.

### Direct Bonding

Various embodiments disclosed herein relate to directly bonded structures in which two or more elements can be directly bonded to one another without an intervening adhesive. Such processes and structures are referred to herein as “direct bonding” processes or “directly bonded” structures. Direct bonding can involve bonding of one material on one element and one material on the other element (also referred to as “uniform” direct bond herein), where the materials on the different elements need not be the same, without traditional adhesive materials. Direct bonding can also involve bonding of multiple materials on one element to multiple materials on the other element (e.g., hybrid bonding).

In some implementations (not illustrated), each bonding layer has one material. In these uniform direct bonding processes, only one material on each element is directly bonded. Example uniform direct bonding processes include the ZIBOND techniques commercially available from Adeia of San Jose, CA. The materials of opposing bonding layers on the different elements can be the same or different, and may comprise elemental or compound materials. For example, in some embodiments, nonconductive bonding layers can be blanket deposited over the base substrate portions without being patterned with conductive features (e.g., without pads). In other embodiments, the bonding layers can be patterned on one or both elements, and can be the same or different from one another, but one material from each element is directly bonded without adhesive across surfaces of the elements (or across the surface of the smaller element if the elements are differently-sized). In another implementation of uniform direct bonding, one or both of the nonconductive bonding layers may include one or more conductive features, but the conductive features are not involved in the bonding. For example, in some implementations, opposing nonconductive bonding layers can be uniformly directly bonded to one another, and through substrate vias (TSVs) can be subsequently formed through one element after bonding to provide electrical communication to the other element.

In various embodiments, the bonding layers 108a and/or 108b can comprise a non-conductive material such as a dielectric material or an undoped semiconductor material, such as undoped silicon, which may include native oxide. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some embodiments, the dielectric materials at the bonding surface do not comprise polymer materials, such as epoxy (e.g., epoxy adhesives, cured epoxies, or epoxy composites such as FR-4 materials), resin or molding materials.

In other embodiments, the bonding layers can comprise an electrically conductive material, such as a deposited conductive oxide material, e.g., indium tin oxide (ITO), as disclosed in U.S. Provisional Patent Application No. 63/524,564, filed Jun. 30, 2023, the entire contents of which is incorporated by reference herein in its entirety for providing examples of conductive bonding layers without shorting contacts through the interface.

In direct bonding, first and second elements can be directly bonded to one another without an adhesive, which is different from a deposition process and results in a structurally different interface compared to that produced by deposition. In one application, a width of the first element in the bonded structure is similar to a width of the second element. In some other embodiments, a width of the first element in the bonded structure is different from a width of the second element. The width or area of the larger element in the bonded structure may be at least 10% larger than the width or area of the smaller element. Further, the interface between directly bonded structures, unlike the interface beneath deposited layers, can include a defect region in which nanometer-scale voids (nanovoids) are present. The nanovoids may be formed due to activation of one or both of the bonding surfaces (e.g., exposure to a plasma, explained below).

The bond interface between non-conductive bonding surfaces can include a higher concentration of materials from the activation and/or last chemical treatment processes compared to the bulk of the bonding layers. For example, in embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH2 molecules, yielding a nitrogen-terminated surface. In embodiments that utilize an oxygen plasma for activation, an oxygen concentration peak can be formed at the bond interface between non-conductive bonding surfaces. In some embodiments, the bond interface can comprise silicon oxynitride, silicon oxycarbonitride, or silicon carbonitride. The direct bond can comprise a covalent bond, which is stronger than van Der Waals bonds. The bonding layers can also comprise polished surfaces that are planarized to a high degree of smoothness.

In direct bonding processes, such as uniform direct bonding and hybrid bonding, two elements are bonded together without an intervening adhesive. In non-direct bonding processes that utilize an adhesive, an intervening material is typically applied to one or both elements to effectuate a physical connection between the elements. For example, in some adhesive-based processes, a flowable adhesive (e.g., an organic adhesive, such as an epoxy), which can include conductive filler materials, can be applied to one or both elements and cured to form the physical (rather than chemical or covalent) connection between elements. Typical organic adhesives lack strong chemical or covalent bonds with either element. In such processes, the connections between the elements are weak and/or readily reversed, such as by reheating or defluxing.

By contrast, direct bonding processes join two elements by forming strong chemical bonds (e.g., covalent bonds) between opposing nonconductive materials. For example, in direct bonding processes between nonconductive materials, one or both nonconductive surfaces of the two elements are planarized and chemically prepared (e.g., activated and/or terminated) such that when the elements are brought into contact, strong chemical bonds (e.g., covalent bonds) are formed, which are stronger than Van der Waals or hydrogen bonds. In some implementations (e.g., between opposing dielectric surfaces, such as opposing silicon oxide surfaces), the chemical bonds can occur spontaneously at room temperature upon being brought into contact. In some implementations, the chemical bonds between opposing non-conductive materials can be strengthened after annealing the elements.

As noted above, hybrid bonding is a species of direct bonding in which both non-conductive features directly bond to non-conductive features, and conductive features directly bond to conductive features of the elements being bonded. The non-conductive bonding materials and interface can be as described above, while the conductive bond can be formed, for example, as a direct metal-to-metal connection. In conventional metal bonding processes, a fusible metal alloy (e.g., solder) can be provided between the conductors of two elements, heated to melt the alloy, and cooled to form the connection between the two elements. The resulting bond often evinces sharp interfaces with conductors from both elements, and is subject to reversal by reheating. By way of contrast, direct metal bonding as employed in hybrid bonding does not require melting or an intermediate fusible metal alloy, and can result in strong mechanical and electrical connections, often demonstrating interdiffusion of the bonded conductive features with grain growth across the bonding interface between the elements, even without the much higher temperatures and pressures of thermocompression bonding.

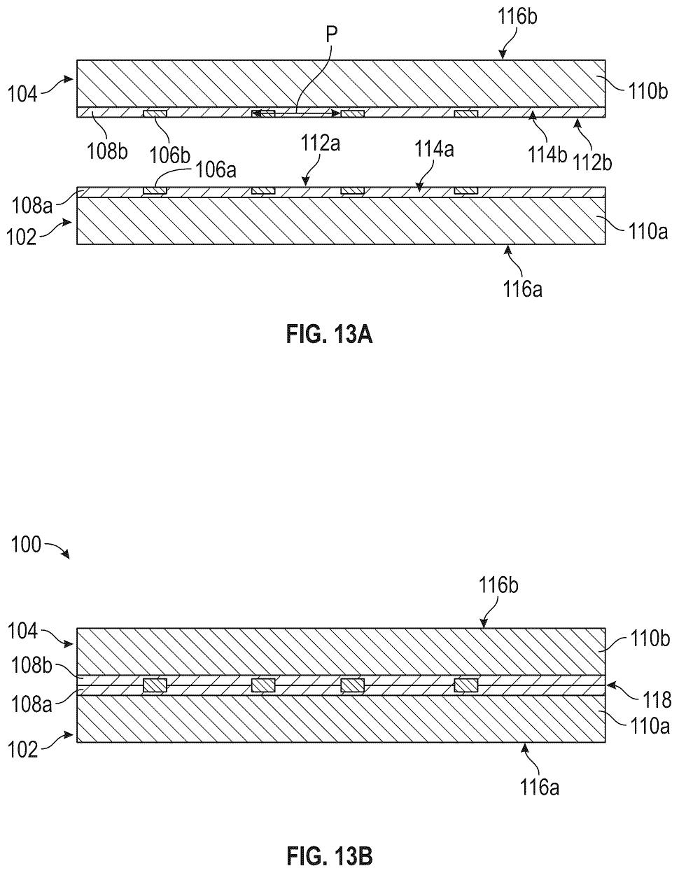

FIGS. 13A and 13B schematically illustrate cross-sectional side views of first and second elements 102, 104 prior to and after, respectively, a process for forming a directly bonded structure, and more particularly a hybrid bonded structure, according to some embodiments. In FIG. 13B, a bonded structure 100 comprises the first and second elements 102 and 104 that are directly bonded to one another at a bond interface 118 without an intervening adhesive. Conductive features 106a of a first element 102 may be electrically connected to corresponding conductive features 106b of a second element 104. In the illustrated hybrid bonded structure 100, the conductive features 106a are directly bonded to the corresponding conductive features 106b without intervening solder or conductive adhesive.

The conductive features 106a and 106b of the illustrated embodiment are embedded in, and can be considered part of, a first bonding layer 108a of the first element 102 and a second bonding layer 108b of the second element 104, respectively. Field regions of the bonding layers 108a, 108b extend between and partially or fully surround the conductive features 106a, 106b. The bonding layers 108a, 108b can comprise layers of non-conductive materials suitable for direct bonding, as described above, and the field regions are directly bonded to one another without an adhesive. The non-conductive bonding layers 108a, 108b can be disposed on respective front sides 114a, 114b of base substrate portions 110a, 110b.

The first and second elements 102, 104 can comprise microelectronic elements, such as semiconductor elements, including, for example, integrated device dies, wafers, passive devices, discrete active devices such as power switches, MEMS, etc. In some embodiments, the base substrate portion can comprise a device portion, such as a bulk semiconductor (e.g., silicon) portion of the elements 102, 104, and back-end-of-line (BEOL) interconnect layers over such semiconductor portions. The bonding layers 108a, 108b can be provided as part of such BEOL layers during device fabrication, as part of redistribution layers (RDL), or as specific bonding layers added to existing devices, with bond pads extending from underlying contacts. Active devices and/or circuitry can be patterned and/or otherwise disposed in or on the base substrate portions 110a, 110b, and can electrically communicate with at least some of the conductive features 106a, 106b. Active devices and/or circuitry can be disposed at or near the front sides 114a, 114b of the base substrate portions 110a, 110b, and/or at or near opposite backsides 116a, 116b of the base substrate portions 110a, 110b. In other embodiments, the base substrate portions 110a, 110b may not include active circuitry, but may instead comprise dummy substrates, passive interposers, passive optical elements (e.g., glass substrates, gratings, lenses), etc. The bonding layers 108a, 108b are shown as being provided on the front sides of the elements, but similar bonding layers can be additionally or alternatively provided on the back sides of the elements.

In some embodiments, the base substrate portions 110a, 110b can have significantly different coefficients of thermal expansion (CTEs), and bonding elements that include such different based substrate portions can form a heterogenous bonded structure. The CTE difference between the base substrate portions 110a and 110b, and particularly between bulk semiconductor (typically single crystal) portions of the base substrate portions 110a, 110b, can be greater than 5 ppm/° C. or greater than 10 ppm/° C. For example, the CTE difference between the base substrate portions 110a and 110b can be in a range of 5 ppm/° C. to 100 ppm/° C., 5 ppm/° C. to 40 ppm/° C., 10 ppm/° C. to 100 ppm/° C., or 10 ppm/° C. to 40 ppm/° C.

In some embodiments, one of the base substrate portions 110a, 110b can comprise optoelectronic single crystal materials, including perovskite materials, that are useful for optical piezoelectric or pyroelectric applications, and the other of the base substrate portions 110a, 110b comprises a more conventional substrate material. For example, one of the base substrate portions 110a, 110b comprises lithium tantalate (LiTaO₃) or lithium niobate (LiNbO₃), and the other one of the base substrate portions 110a, 110b comprises silicon (Si), quartz, fused silica glass, sapphire, or a glass. In other embodiments, one of the base substrate portions 110a, 110b comprises a III-V single semiconductor material, such as gallium arsenide (GaAs) or gallium nitride (GaN), and the other one of the base substrate portions 110a, 110b can comprise a non-III-V semiconductor material, such as silicon (Si), or can comprise other materials with similar CTE, such as quartz, fused silica glass, sapphire, or a glass. In still other embodiments, one of the base substrate portions 110a, 110b comprises a semiconductor material and the other of the base substrate portions 110a, 110b comprises a packaging material, such as a glass, organic or ceramic substrate.

In some arrangements, the first element 102 can comprise a singulated element, such as a singulated integrated device die. In other arrangements, the first element 102 can comprise a carrier or substrate (e.g., a semiconductor wafer) that includes a plurality (e.g., tens, hundreds, or more) of device regions that, when singulated, forms a plurality of integrated device dies, though in other embodiments such a carrier can be a package substrate or a passive or active interposer. Similarly, the second element 104 can comprise a singulated element, such as a singulated integrated device die. In other arrangements, the second element 104 can comprise a carrier or substrate (e.g., a semiconductor wafer). The embodiments disclosed herein can accordingly apply to wafer-to-wafer (W2W), die-to-die (D2D), or die-to-wafer (D2W) bonding processes. In W2W processes, two or more wafers can be directly bonded to one another (e.g., direct hybrid bonded) and singulated using a suitable singulation process. After singulation, side edges of the singulated structure (e.g., the side edges of the two bonded elements) can be substantially flush (substantially aligned x-y dimensions) and/or the edges of the bonding interfaces for both bonded and singulated elements can be coextensive, and may include markings indicative of the common singulation process for the bonded structure (e.g., saw markings if a saw singulation process is used).

While only two elements 102, 104 are shown, any suitable number of elements can be stacked in the bonded structure 100. For example, a third element (not shown) can be stacked on the second element 104, a fourth element (not shown) can be stacked on the third element, and so forth. In such implementations, through substrate vias (TSVs) can be formed to provide vertical electrical communication between and/or among the vertically-stacked elements. Additionally or alternatively, one or more additional elements (not shown) can be stacked laterally adjacent one another along the first element 102. In some embodiments, a laterally stacked additional element may be smaller than the second element. In some embodiments, the bonded structure can be encapsulated with an insulating material, such as an inorganic dielectric (e.g., silicon oxide, silicon nitride, silicon oxynitrocarbide, etc.). One or more insulating layers can be provided over the bonded structure. For example, in some implementations, a first insulating layer can be conformally deposited over the bonded structure, and a second insulating layer (which may include be the same material as the first insulating layer, or a different material) can be provided over the first insulating layer.

To effectuate direct bonding between the bonding layers 108a, 108b, the bonding layers 108a, 108b can be prepared for direct bonding. Non-conductive bonding surfaces 112a, 112b at the upper or exterior surfaces of the bonding layers 108a, 108b can be prepared for direct bonding by polishing, for example, by chemical mechanical polishing (CMP). The roughness of the polished bonding surfaces 112a, 112b can be less than 30 Å rms. For example, the roughness of the bonding surfaces 112a and 112b can be in a range of about 0.1 Å rms to 15 Å rms, 0.5 Å rms to 10 Å rms, or 1 Å rms to 5 Å rms. Polishing can also be tuned to leave the conductive features 106a, 106b recessed relative to the field regions of the bonding layers 108a, 108b.

Preparation for direct bonding can also include cleaning and exposing one or both of the bonding surfaces 112a, 112b to a plasma and/or etchants to activate at least one of the surfaces 112a, 112b. In some embodiments, one or both of the surfaces 112a, 112b can be terminated with a species after activation or during activation (e.g., during the plasma and/or etch processes). Without being limited by theory, in some embodiments, the activation process can be performed to break chemical bonds at the bonding surface(s) 112a, 112b, and the termination process can provide additional chemical species at the bonding surface(s) 112a, 112b that alters the chemical bond and/or improves the bonding energy during direct bonding. In some embodiments, the activation and termination are provided in the same step, e.g., a plasma to activate and terminate the surface(s) 112a, 112b. In other embodiments, one or both of the bonding surfaces 112a, 112b can be terminated in a separate treatment to provide the additional species for direct bonding. In various embodiments, the terminating species can comprise nitrogen. For example, in some embodiments, the bonding surface(s) 112a, 112b can be exposed to a nitrogen-containing plasma. Other terminating species can be suitable for improving bonding energy, depending upon the materials of the bonding surfaces 112a, 112b. Further, in some embodiments, the bonding surface(s) 112a, 112b can be exposed to fluorine. For example, there may be one or multiple fluorine concentration peaks at or near a bond interface 118 between the first and second elements 102, 104. Typically, fluorine concentration peaks occur at interfaces between material layers. Additional examples of activation and/or termination treatments may be found in U.S. Pat. No. 9,391,143 at Col. 5, line 55 to Col. 7, line 3; Col. 8, line 52 to Col. 9, line 45; Col. 10, lines 24-36; Col. 11, lines 24-32, 42-47, 52-55, and 60-64; Col. 12, lines 3-14, 31-33, and 55-67; Col. 14, lines 38-40 and 44-50; and 10,434,749 at Col. 4, lines 41-50; Col. 5, lines 7-22, 39, 55-61; Col. 8, lines 25-31, 35-40, and 49-56; and Col. 12, lines 46-61, the activation and termination teachings of which are incorporated by reference herein.

Thus, in the directly bonded structure 100, the bond interface 118 between two non-conductive materials (e.g., the bonding layers 108a, 108b) can comprise a very smooth interface with higher nitrogen (or other terminating species) content and/or fluorine concentration peaks at the bond interface 118. In some embodiments, the nitrogen and/or fluorine concentration peaks may be detected using various types of inspection techniques, such as SIMS techniques. The polished bonding surfaces 112a and 112b can be slightly rougher (e.g., about 1 Å rms to 30 Å rms, 3 Å rms to 20 Å rms, or possibly rougher) after an activation process. In some embodiments, activation and/or termination can result in slightly smoother surfaces prior to bonding, such as where a plasma treatment preferentially erodes high points on the bonding surface.

The non-conductive bonding layers 108a and 108b can be directly bonded to one another without an adhesive. In some embodiments, the elements 102, 104 are brought together at room temperature, without the need for application of a voltage, and without the need for application of external pressure or force beyond that used to initiate contact between the two elements 102, 104. Contact alone can cause direct bonding between the non-conductive surfaces of the bonding layers 108a, 108b (e.g., covalent dielectric bonding). Subsequent annealing of the bonded structure 100 can cause the conductive features 106a, 106b to directly bond.

In some embodiments, prior to direct bonding, the conductive features 106a, 106b are recessed relative to the surrounding field regions, such that a total gap between opposing contacts after dielectric bonding and prior to anneal is less than 15 nm, or less than 10 nm. Because the recess depths for the conductive features 106a and 106b can vary across each element, due to process variation, the noted gap can represent a maximum or an average gap between corresponding conductive features 106a, 106b of two joined elements (prior to anneal). Upon annealing, the conductive features 106a and 106b can expand and contact one another to form a metal-to-metal direct bond.

During annealing, the conductive features 106a, 106b (e.g., metallic material) can expand while the direct bonds between surrounding non-conductive materials of the bonding layers 108a, 108b resist separation of the elements, such that the thermal expansion increases the internal contact pressure between the opposing conductive features. Annealing can also cause metallic grain growth across the bonding interface, such that grains from one element migrate across the bonding interface at least partially into the other element, and vice versa. Thus, in some hybrid bonding embodiments, opposing conductive materials are joined without heating above the conductive materials' melting temperature, such that bonds can form with lower anneal temperatures compared to soldering or thermocompression bonding.

In various embodiments, the conductive features 106a, 106b can comprise discrete pads, contacts, electrodes, or traces at least partially embedded in the non-conductive field regions of the bonding layers 108a, 108b. In some embodiments, the conductive features 106a, 106b can comprise exposed contact surfaces of TSVs (e.g., through silicon vias).

As noted above, in some embodiments, in the elements 102, 104 of FIG. 13A prior to direct bonding, portions of the respective conductive features 106a and 106b can be recessed below the non-conductive bonding surfaces 112a and 112b, for example, recessed by less than 30 nm, less than 20 nm, less than 15 nm, or less than 10 nm, for example, recessed in a range of 2 nm to 20 nm, or in a range of 4 nm to 10 nm. Due to process variation, both dielectric thickness and conductor recess depths can vary across an element. Accordingly, the above recess depth ranges may apply to individual conductive features 106a, 106b or to average depths of the recesses relative to local non-conductive field regions. Even for an individual conductive feature 106a, 106b, the vertical recess can vary across the feature, and so can be measured at or near the lateral middle or center of the cavity in which a given conductive feature 106a, 106b is formed, or can be measured at the sides of the cavity.

Beneficially, the use of hybrid bonding techniques (such as Direct Bond Interconnect, or DBIR, techniques commercially available from Adeia of San Jose, CA) can enable high density of connections between conductive features 106a, 106b across the direct bond interface 118 (e.g., small or fine pitches for regular arrays).

In some embodiments, a pitch p of the conductive features 106a, 106b, such as conductive traces embedded in the bonding surface of one of the bonded elements, may be less than 40 μm, less than 20 μm, less than 10 μm, less than 5 μm, less than 2 μm, or even less than 1 μm. For some applications, the ratio of the pitch of the conductive features 106a and 106b to one of the lateral dimensions (e.g., a diameter) of the bonding pad is less than is less than 20, or less than 10, or less than 5, or less than 3 and sometimes desirably less than 2. In various embodiments, the conductive features 106a and 106b and/or traces can comprise copper or copper alloys, although other metals may be suitable, such as nickel, aluminum, or alloys thereof. The conductive features disclosed herein, such as the conductive features 106a and 106b, can comprise fine-grain metal (e.g., a fine-grain copper). Further, a major lateral dimension (e.g., a pad diameter) can be small as well, e.g., in a range of about 0.25 μm to 30 μm, in a range of about 0.25 μm to 5 μm, or in a range of about 0.5 μm to 5 μm.

For hybrid bonded elements 102, 104, as shown, the orientations of one or more conductive features 106a, 106b from opposite elements can be opposite to one another. As is known in the art, conductive features in general can be formed with close to vertical sidewalls, particularly where directional reactive ion etching (RIE) defines the conductor sidewalls either directly though etching the conductive material or indirectly through etching surrounding insulators in damascene processes. However, some slight taper to the conductor sidewalls can be present, wherein the conductor becomes narrower farther away from the surface initially exposed to the etch. The taper can be even more pronounced when the conductive sidewall is defined directly or indirectly with isotropic wet or dry etching. In the illustrated embodiment, at least one conductive feature 106b in the bonding layer 108b (and/or at least one internal conductive feature, such as a BEOL feature) of the upper element 104 may be tapered or narrowed upwardly, away from the bonding surface 112b. By way of contrast, at least one conductive feature 106a in the bonding layer 108a (and/or at least one internal conductive feature, such as a BEOL feature) of the lower element 102 may be tapered or narrowed downwardly, away from the bonding surface 112a. Similarly, any bonding layers (not shown) on the backsides 116a, 116b of the elements 102, 104 may taper or narrow away from the backsides, with an opposite taper orientation relative to front side conductive features 106a, 106b of the same element.

As described above, in an anneal phase of hybrid bonding, the conductive features 106a, 106b can expand and contact one another to form a metal-to-metal direct bond. In some embodiments, the materials of the conductive features 106a, 106b of opposite elements 102, 104 can interdiffuse during the annealing process. In some embodiments, metal grains grow into each other across the bond interface 118. In some embodiments, the metal is or includes copper, which can have grains oriented along the 111 crystal plane for improved copper diffusion across the bond interface 118. In some embodiments, the conductive features 106a and 106b may include nanotwinned copper grain structure, which can aid in merging the conductive features during anneal. There is substantially no gap between the non-conductive bonding layers 108a and 108b at or near the bonded conductive features 106a and 106b. In some embodiments, a barrier layer may be provided under and/or laterally surrounding the conductive features 106a and 106b (e.g., which may include copper). In other embodiments, however, there may be no barrier layer under the conductive features 106a and 106b.

### Additional Embodiments

In the foregoing specification, the systems and processes have been described with reference to specific embodiments thereof. It will, however, be evident that various modifications and changes may be made thereto without departing from the broader spirit and scope of the embodiments disclosed herein. The specification and drawings are, accordingly, to be regarded in an illustrative rather than restrictive sense.

Indeed, although the systems and processes have been disclosed in the context of certain embodiments and examples, it will be understood by those skilled in the art that the various embodiments of the systems and processes extend beyond the specifically disclosed embodiments to other alternative embodiments and/or uses of the systems and processes and obvious modifications and equivalents thereof. In addition, while several variations of the embodiments of the systems and processes have been shown and described in detail, other modifications, which are within the scope of this disclosure, will be readily apparent to those of skill in the art based upon this disclosure. It is also contemplated that various combinations or sub-combinations of the specific features and embodiments of the embodiments may be made and still fall within the scope of the disclosure. It should be understood that various features and embodiments of the disclosed embodiments can be combined with, or substituted for, one another in order to form varying modes of the embodiments of the disclosed systems and processes. Any methods disclosed herein need not be performed in the order recited. Thus, it is intended that the scope of the systems and processes herein disclosed should not be limited by the particular embodiments described above.

It will be appreciated that the systems and methods of the disclosure each have several innovative embodiments, no single one of which is solely responsible or required for the desirable attributes disclosed herein. The various features and processes described above may be used independently of one another or may be combined in various ways. All possible combinations and sub-combinations are intended to fall within the scope of this disclosure.

Certain features that are described in this specification in the context of separate embodiments also may be implemented in combination in a single embodiment. Conversely, various features that are described in the context of a single embodiment also may be implemented in multiple embodiments separately or in any suitable sub-combination. Moreover, although features may be described above as acting in certain combinations and even initially claimed as such, one or more features from a claimed combination may in some cases be excised from the combination, and the claimed combination may be directed to a sub-combination or variation of a sub-combination. No single feature or group of features is necessary or indispensable to each and every embodiment.

It will also be appreciated that conditional language used herein, such as, among others, “can,” “could,” “might,” “may,” “for example,” and the like, unless specifically stated otherwise, or otherwise understood within the context as used, is generally intended to convey that certain embodiments include, while other embodiments do not include, certain features, elements and/or steps. Thus, such conditional language is not generally intended to imply that features, elements and/or steps are in any way required for one or more embodiments or that one or more embodiments necessarily include logic for deciding, with or without author input or prompting, whether these features, elements and/or steps are included or are to be performed in any particular embodiment. The terms “comprising,” “including,” “having,” and the like are synonymous and are used inclusively, in an open-ended fashion, and do not exclude additional elements, features, acts, operations, and so forth. In addition, the term “or” is used in its inclusive sense (and not in its exclusive sense) so that when used, for example, to connect a list of elements, the term “or” means one, some, or all of the elements in the list. In addition, the articles “a,” “an,” and “the” as used in this application and the appended claims are to be construed to mean “one or more” or “at least one” unless specified otherwise. Similarly, while operations may be depicted in the drawings in a particular order, it is to be recognized that such operations need not be performed in the particular order shown or in sequential order, or that all illustrated operations be performed, to achieve desirable results. Further, the drawings may schematically depict one or more example processes in the form of a flowchart. However, other operations that are not depicted may be incorporated in the example methods and processes that are schematically illustrated. For example, one or more additional operations may be performed before, after, simultaneously, or between any of the illustrated operations. Additionally, the operations may be rearranged or reordered in other embodiments. Additionally, other embodiments are within the scope of the following claims. In some cases, the actions recited in the claims may be performed in a different order and still achieve desirable results.

Further, while the methods and devices described herein may be susceptible to various modifications and alternative forms, specific examples thereof have been shown in the drawings and are herein described in detail. It should be understood, however, that the embodiments are not to be limited to the particular forms or methods disclosed, but, to the contrary, the embodiments are to cover all modifications, equivalents, and alternatives falling within the spirit and scope of the various implementations described and the appended claims. Further, the disclosure herein of any particular feature, aspect, method, property, characteristic, quality, attribute, element, or the like in connection with an implementation or embodiment can be used in all other implementations or embodiments set forth herein. Any methods disclosed herein need not be performed in the order recited. The methods disclosed herein may include certain actions taken by a practitioner; however, the methods can also include any third-party instruction of those actions, either expressly or by implication. The ranges disclosed herein also encompass any and all overlap, sub-ranges, and combinations thereof. Language such as “up to,” “at least,” “greater than,” “less than,” “between,” and the like includes the number recited. Numbers preceded by a term such as “about” or “approximately” include the recited numbers and should be interpreted based on the circumstances (for example, as accurate as reasonably possible under the circumstances, for example±5%, +10%, +15%, etc.). For example, “about 3.5 mm” includes “3.5 mm.” Phrases preceded by a term such as “substantially” include the recited phrase and should be interpreted based on the circumstances (for example, as much as reasonably possible under the circumstances). For example, “substantially constant” includes “constant.” Unless stated otherwise, all measurements are at standard conditions including temperature and pressure.

As used herein, a phrase referring to “at least one of” a list of items refers to any combination of those items, including single members. As an example, “at least one of: A, B, or C” is intended to cover: A; B; C; A and B; A and C; B and C; and A, B, and C. Conjunctive language such as the phrase “at least one of X, Y and Z,” unless specifically stated otherwise, is understood with the context as used in general to convey that an item, term, etc. may be at least one of X, Y or Z. Thus, such conjunctive language is not generally intended to imply that certain embodiments require at least one of X, at least one of Y, and at least one of Z to each be present. The headings provided herein, if any, are for convenience only and do not necessarily affect the scope or meaning of the devices and methods disclosed herein. Accordingly, the claims are not intended to be limited to the embodiments shown herein but are to be accorded ta fair interpretation consistent with this disclosure, the principles and the novel features disclosed herein.

What is claimed is:

1. A structure comprising:
a first processor die;
a second processor die laterally spaced from the first processor die;
a first memory unit disposed vertically above the first processor die; and
a connecting element disposed vertically between the first memory unit and the first processor die, and vertically between the first memory unit and the second processor die, the connecting element comprising:
a first conductor electrically connecting the first processor die and the second processor die; and
a second conductor electrically connecting the first processor die and the first memory unit.

2. The structure of claim 1, wherein the first memory unit comprises a first stack of memory dies and a first logic die.

3. The structure of claim 2, wherein the first logic die is an input/output (I/O) interface logic die, and is stacked below the first stack of memory dies.

4. The structure of claim 1, wherein the first processor die communicates with the first memory unit at least through the second conductor.

5. The structure of claim 1, wherein the second processor die communicates with the first memory unit at least through the second conductor and the first conductor.

6. The structure of claim 1, further comprising a second memory unit disposed vertically above the second processor die, the second memory unit laterally spaced from the first memory unit, the connecting element disposed vertically between the first memory unit and the first processor die and vertically between the first memory unit and the second processor die.

7. A structure comprising:
a first processor die;
a second processor die laterally spaced from the first processor die;
a first memory unit disposed vertically above the first processor die; and
a connecting element disposed vertically to the first processor die and the second processor die, the connecting element comprising:
a first conductor electrically connecting the first processor die and the second processor die.

8. The structure of claim 7, wherein the first processor die comprises a first via, the second processor die communicating with the first memory unit at least through the first via and the first conductor.

9. The structure of claim 8, wherein the first processor die communicates with the first memory unit at least through the first via.

10. The structure of claim 7, wherein the connecting element is disposed vertically below the first processor die and the second processor die.

11. The structure of claim 7, wherein the connecting element is disposed vertically above the first processor die and the second processor die, the connecting element disposed laterally relative to the first memory unit.

12. The structure of claim 7, wherein the connecting element is disposed vertically between the first memory unit and the first processor die, and vertically between the first memory unit and the second processor die.

13. The structure of claim 12, wherein the connecting element comprises a second conductor electrically connecting the first processor die and the first memory unit.

14. The structure of claim 13, wherein the first processor die communicates with the first memory unit at least through the second conductor.

15. The structure of claim 13, wherein the second processor die communicates with the first memory unit at least through the second conductor and the first conductor.

16. The structure of claim 12, further comprising a second memory unit disposed vertically above the second processor die, the second memory unit laterally spaced from the first memory unit, the connecting element disposed vertically between the first memory unit and the first processor die and vertically between the first memory unit and the second processor die.

17. The structure of claim 16, wherein the connecting element comprises a third conductor electrically connecting the second processor die and the second memory unit.

18. A structure comprising:
a first processor die;
a second processor die laterally spaced from the first processor die;
a third die laterally spaced from the first processor die and the second processor die;
a first memory unit disposed vertically above the first processor die, the second processor die and the third die; and
a connecting element disposed vertically between the first memory unit and the first processor die, vertically between the first memory unit and the second processor die, and vertically between the first memory unit and the third die, the connecting element comprising:
a first conductor electrically connecting the first processor die, the second processor die, and the third die; and
a second conductor electrically connecting at least the first processor die and the first memory unit.

19. The structure of claim 18, wherein the first memory unit comprises a first stack of memory dies and a first input/output (I/O) interface logic.

20. The structure of claim 18, wherein the connecting element is hybrid bonded to the first processor die, the second processor die, and the third die.
